(19) United States
(12) Patent Application Publication
(10) Pub. No.: US 2023/0172016 A1
(43) Pub. Date: Jun. 1, 2023

(54) DISPLAY DEVICE

(71) Applicant: Samsung Display Co., Ltd., Yongin-si (KR)

(72) Inventors: HYUNGKEUN PARK, Seoul (KR); SUNMI KANG, Cheonan-si (KR); JUHOON KANG, Hwaseong-si (KR); DONGHWAN SHIM, Hwaseong-si (KR); SEOKHYUN LIM, Hwaseong-si (KR); JOOHEE JEON, Hwaseong-si (KR); MIYEON CHO, Seoul (KR); GUN HEE KIM, Seoul (KR); SUNYOUNG JUNG, Suwon-si (KR)

(73) Assignee: Samsung Display Co., Ltd., Yongin-si (KR)

(21) Appl. No.: 17/963,382

(22) Filed: Oct. 11, 2022

(30) Foreign Application Priority Data
Nov. 30, 2021 (KR) 10-2021-0168803

(51) Int. Cl. H01L 27/32; H01L 27/12

(52) U.S. Cl. CPC H01L 27/3276; H01L 27/3262; H01L 27/124; H01L 27/1225

(57) ABSTRACT

A display device including a display panel including a display area, a non-display area, a pixel disposed in the display area and including a light emitting element and a pixel driving circuit electrically connected to the light emitting element, a data line electrically connected to the pixel and extending in a first direction, a plurality of scan lines electrically connected to the pixel and extending in a second direction intersecting the first direction, an emission control line electrically connected to the pixel and extending in the second direction, and a first initialization voltage line electrically connected to the pixel, extending in the second direction, and to which a first initialization voltage is applied. The first initialization voltage line is disposed between one of the plurality of scan lines and the emission control line and another of the plurality of scan lines and the emission control line.

### CROSS-REFERENCE TO RELATED APPLICATION(S)

This application claims priority to and benefits of Korean Patent Application No. 10-2021-0168803 under 35 U.S.C. § 119, filed on Nov. 30, 2021 in the Korean Intellectual Property Office, the entire contents of which are herein incorporated by reference.

### BACKGROUND

### 1. Technical Field

Embodiments of the disclosure relate to a display device having a highly-integrated line arrangement.

### 2. Description of the Related Art

A display device may include pixels and a driving circuit (e.g., including a scan driver and a data driver) controlling the pixels. Each of the pixels may include a display element and a pixel driving circuit controlling a display element. The pixel driving circuit may be connected with multiple lines and may be controlled through the lines.

### SUMMARY

Embodiments of the disclosure provide a display device having a highly-integrated line arrangement.

Embodiments of the disclosure provide a display device having a highly-integrated line arrangement in which noise shielding performance may be improved.

According to an embodiment, a display device may include a display panel including a display area, a non-display area, a pixel that may be disposed in the display area and including a light emitting element and a pixel driving circuit electrically connected to the light emitting element, a data line electrically connected to the pixel and extends in a first direction, a plurality of scan lines electrically connected to the pixel and extending in a second direction intersecting the first direction, an emission control line electrically connected to the pixel, and extending in the second direction, and a first initialization voltage line electrically connected to the pixel, extending in the second direction, and to which a first initialization voltage may be applied. The first initialization voltage line may be disposed between one of the plurality of scan lines and the emission control line and another of the plurality of scan lines and the emission control line.

The plurality of scan lines may include an initialization scan line, a compensation scan line, and a write scan line, and at least one of the initialization scan line, the compensation scan line, and the write scan line and at least another of the initialization scan line, the compensation scan line, and the write scan line are disposed on different layers.

The pixel driving circuit may include a driving thin film transistor electrically connected between a driving voltage line receiving a driving voltage and the light emitting element, a switching thin film transistor electrically connected between the data line and a first electrode of the driving thin film transistor and that receives a first write scan signal, a compensation thin film transistor electrically connected between a second electrode of the driving thin film transistor and a first node, and that receives a compensation scan signal, a first initialization thin film transistor electrically connected between the first initialization voltage line and the first node, and that receives an initialization scan signal, and a second initialization thin film transistor electrically connected between the first initialization voltage line and an anode of the light emitting element, and that receives a second write scan signal. The first write scan signal may be provided through the write scan line, the compensation scan signal may be provided through the compensation scan line, the initialization scan signal may be provided through the initialization scan line, and the second write scan signal may be provided through a write scan line electrically connected to a switching transistor of another pixel.

In a plan view, the first initialization voltage line may overlap the write scan line and the initialization scan line. In a cross-sectional view, the first initialization voltage line may be disposed between the write scan line and the initialization scan line.

The pixel driving circuit may further include an operation control thin film transistor electrically connected between the driving voltage line and the driving thin film transistor, and that receives an emission control signal through the emission control line, and an emission control thin film transistor electrically connected between the driving thin film transistor and the light emitting element, and that receives the emission control signal through the emission control line.

In a plan view, the compensation scan line may overlap the emission control line.

The display panel may further include a shielding line overlapping the compensation scan line in a plan view. In a plan view, the compensation scan line, the shielding line, and the emission control line may overlap each other, and the shielding line may be disposed between the compensation scan line and the emission control line.

The driving thin film transistor, the switching thin film transistor, the second initialization thin film transistor, the operation control thin film transistor, and the emission control thin film transistor may be P-type transistors, and the compensation thin film transistor and the first initialization thin film transistor may be N-type transistors.

Each of the driving thin film transistor, the switching thin film transistor, the second initialization thin film transistor, the operation control thin film transistor, and the emission control thin film transistor may be a transistor having a first semiconductor pattern, and each of the compensation thin film transistor and the first initialization thin film transistor may be a transistor having a second semiconductor pattern, the first semiconductor pattern and the second semiconductor pattern being disposed on different layers.

In a plan view, the first semiconductor pattern and the second semiconductor pattern may not overlap each other.

In a plan view, at least a portion of the second semiconductor pattern may overlap a portion of the first semiconductor pattern.

In a plan view, the first initialization thin film transistor may overlap the second initialization thin film transistor or may overlap the switching thin film transistor.

The display device may further include a first additional constant voltage line that overlaps a portion of the second semiconductor pattern and the compensation scan line in a plan view, and a second additional constant voltage line that overlaps another portion of the second semiconductor pattern and the initialization scan line in a plan view.

A negative constant voltage may be applied to each of the first additional constant voltage line and the second additional constant voltage line.

The first semiconductor pattern may include a silicon semiconductor, and the second semiconductor pattern may include an oxide semiconductor.

The display panel may further include a second initialization voltage line electrically connected to the pixel, extending in the second direction, and to which a second initialization voltage different from the first initialization voltage may be applied, and the second initialization voltage line may overlap at least one of the plurality of scan lines and the emission control line in a plan view.

The pixel driving circuit may include a driving thin film transistor electrically connected between a driving voltage line receiving a driving voltage and the light emitting element, a switching thin film transistor electrically connected between the data line and a first electrode of the driving thin film transistor, and that receives a first write scan signal, a compensation thin film transistor electrically connected between a second electrode of the driving thin film transistor and a first node, and that receives a compensation scan signal, a first initialization thin film transistor electrically connected between the first initialization voltage line and the first node, and that receives an initialization scan signal, and a second initialization thin film transistor electrically connected between the second initialization voltage line and an anode of the light emitting element, and that receives a second write scan signal.

Each of the first initialization voltage and the second initialization voltage may be a negative constant voltage.

According to an embodiment, a display device may include a display panel including a display area, a non-display area, a pixel disposed in the display area and including a light emitting element and a pixel driving circuit electrically connected to the light emitting element, a data line electrically connected to the pixel, a plurality of scan lines electrically connected to the pixel, an emission control line electrically connected to the pixel, a first initialization voltage line electrically connected to the pixel, and a second initialization voltage line electrically connected to the pixel. The plurality of scan lines, the emission control line, and the first and second initialization voltage lines may extend in the same direction. In a plan view, three lines of the plurality of scan lines, the emission control line, and the first and second initialization voltage lines may overlap each other.

The pixel driving circuit may include a driving thin film transistor electrically connected between a driving voltage line receiving a driving voltage and the light emitting element, a switching thin film transistor electrically connected between the data line and a first electrode of the driving thin film transistor, and that receives a first write scan signal, a compensation thin film transistor electrically connected between a second electrode of the driving thin film transistor and a first node, and that receives a compensation scan signal, a first initialization thin film transistor electrically connected between the first initialization voltage line and the first node, and that receives an initialization scan signal, a second initialization thin film transistor electrically connected between the second initialization voltage line and an anode of the light emitting element, and that receives a second write scan signal, an operation control thin film transistor electrically connected between the driving voltage line and the driving thin film transistor, and that receives an emission control signal through the emission control line, and an emission control thin film transistor electrically connected between the driving thin film transistor and the light emitting element, and that receives the emission control signal through the emission control line.

A first line being one of the three lines may be one of the first and second initialization voltage lines, a second line being another of the three lines may be a scan line electrically connected to the compensation thin film transistor or the first initialization thin film transistor from among the plurality of scan lines, and a third line being another of the three lines may be a scan line electrically connected to the switching thin film transistor from among the plurality of scan lines or the emission control line.

The first line may be disposed between the second line and the third line.

The three lines may not overlap the driving thin film transistor in a plan view.

A first constant voltage may be applied to the first initialization voltage line, and a second constant voltage different from the first constant voltage may be applied to the second initialization voltage line.

Each of the driving thin film transistor, the switching thin film transistor, the second initialization thin film transistor, the operation control thin film transistor, and the emission control thin film transistor may be a transistor having a silicon semiconductor layer. Each of the compensation thin film transistor and the first initialization thin film transistor may be a transistor having an oxide semiconductor layer. In a plan view, a portion of the oxide semiconductor layer may overlap a portion of the oxide semiconductor layer.

In a plan view, the first initialization thin film transistor may overlap the second initialization thin film transistor or the switching thin film transistor.

The display device may further include a first additional constant voltage line that overlaps a portion of the oxide semiconductor layer and a first line among the three lines in a plan view, and a second additional constant voltage line that overlaps another portion of the oxide semiconductor layer and a second line among the three lines in a plan view.

According to an embodiment, a display device may include a display panel including a display area, a non-display area, a pixel disposed in the display area and including a light emitting element and a pixel driving circuit electrically connected to the light emitting element and including a plurality of transistors, a data line electrically connected to the pixel and extending in a first direction, a plurality of scan lines electrically connected to the pixel and extending in a second direction intersecting the first direction, an emission control line electrically connected to the pixel, and a constant voltage line to which a constant voltage may be provided and overlapping the pixel driving circuit in a plan view. At least one of the plurality of transistors may include an oxide semiconductor layer. Others of the plurality of transistors may include a silicon semiconductor layer, the silicon semiconductor layer and the oxide semiconductor layer being disposed on different layers. In a plan view, a portion of the oxide semiconductor layer and a portion of the silicon semiconductor layer may overlap each other.

In a plan view, three lines of the plurality of scan lines, the emission control line, and the constant voltage line may overlap each other.

The constant voltage line may be disposed between one of the plurality of scan lines and the emission control line and another of the plurality of scan lines and the emission control line.

### BRIEF DESCRIPTION OF THE DRAWINGS

The above and other aspects and features of the disclosure will become apparent by describing in detail embodiments thereof with reference to the accompanying drawings, of which:

FIG. 1 is a schematic perspective view of a display device according to an embodiment of the disclosure.

FIG. 2 is a schematic cross-sectional view of a display device according to an embodiment of the disclosure.

FIG. 3 is a schematic block diagram of a display device according to an embodiment of the disclosure.

FIG. 4 is a schematic circuit diagram illustrating a pixel according to an embodiment of the disclosure.

FIG. 5 is a schematic waveform diagram of driving signals for driving a pixel illustrated in FIG. 4.

FIG. 6A is a schematic cross-sectional view illustrating a pixel of a display panel according to an embodiment of the disclosure.

FIG. 6B is a schematic cross-sectional view illustrating a stacked structure of an emission layer according to an embodiment of the disclosure.

FIG. 6C is a schematic cross-sectional view illustrating a stacked structure of an emission layer according to an embodiment of the disclosure.

FIG. 6D is a schematic cross-sectional view illustrating a stacked structure of an emission layer according to an embodiment of the disclosure.

FIG. 6E is a schematic cross-sectional view illustrating a stacked structure of an emission layer according to an embodiment of the disclosure.

FIGS. 6F, 6G, and 6H are schematic cross-sectional views illustrating stacked structures of light emitting elements respectively disposed in emission areas, according to an embodiment of the disclosure.

FIG. 7A is a schematic plan view illustrating a portion of a pixel driving circuit according to a comparative example of the disclosure.

FIG. 7B is a schematic cross-sectional view taken along line I-I′ of FIG. 7A.

FIG. 8A is a schematic plan view illustrating a portion of a pixel driving circuit according to an embodiment of the disclosure.

FIG. 8B is a schematic cross-sectional view taken along line II-II′ of FIG. 8A.

FIG. 9A is a schematic plan view illustrating a portion of a pixel driving circuit according to an embodiment of the disclosure.

FIG. 9B is a schematic cross-sectional view taken along line III-III′ of FIG. 9A.

FIG. 9C is a schematic cross-sectional view illustrating a portion of a pixel driving circuit according to an embodiment of the disclosure.

FIG. 9D is a schematic cross-sectional view illustrating a portion of a pixel driving circuit according to an embodiment of the disclosure.

FIG. 10A is a schematic plan view illustrating a portion of a pixel driving circuit according to an embodiment of the disclosure.

FIG. 10B is a schematic cross-sectional view taken along line IV-IV′ of FIG. 10A.

FIG. 10C is a schematic cross-sectional view illustrating a portion of a pixel driving circuit according to an embodiment of the disclosure.

FIG. 11A is a schematic plan view illustrating a portion of a pixel driving circuit according to an embodiment of the disclosure.

FIG. 11B is a schematic cross-sectional view taken along line V-V′ of FIG. 11A.

FIG. 12 is a schematic plan view illustrating a portion of a pixel driving circuit according to an embodiment of the disclosure.

FIG. 13A is a schematic plan view illustrating a portion of a pixel driving circuit according to an embodiment of the disclosure.

FIG. 13B is a schematic cross-sectional view taken along line VI-VI′ of FIG. 13A.

FIG. 14 is a schematic plan view illustrating a portion of a pixel driving circuit according to an embodiment of the disclosure.

FIG. 15 is a schematic circuit diagram illustrating a pixel according to an embodiment of the disclosure.

FIG. 16A is a schematic plan view illustrating a portion of a pixel driving circuit according to an embodiment of the disclosure.

FIG. 16B is a schematic cross-sectional view taken along line VII-VII′ of FIG. 16A.

FIG. 16C is a schematic cross-sectional view illustrating a portion of a pixel driving circuit according to an embodiment of the disclosure.

FIG. 17A is a schematic plan view illustrating a portion of a pixel driving circuit according to an embodiment of the disclosure.

FIG. 17B is a schematic cross-sectional view taken along line VIII-VIII′ of FIG. 17A.

FIG. 18 is a schematic plan view illustrating a portion of a pixel driving circuit according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the disclosure, the expression that a first component (or area, layer, part, portion, etc.) is “on”, “connected with”, or “coupled to” a second component means that the first component may be directly on, connected with, or coupled to the second component or means that a third component may be disposed therebetween.

The same reference numerals refer to the same components. Also, in drawings, thicknesses, proportions, and dimensions of components may be exaggerated to describe the technical features effectively.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Although the terms “first”, “second”, etc. may be used to describe various components, the components should not be construed as being limited by the terms. The terms are only used to distinguish one component from another component. For example, without departing from the scope and spirit of the disclosure, a first component may be referred to as a second component, and similarly, the second component may be referred to as the first component. The singular forms are intended to include the plural forms unless the context clearly indicates otherwise.

Also, the terms “under”, “below”, “lower”, “on”, “above”, “upper”, etc. are used to describe the correlation of components illustrated in drawings. The terms are relative in concept and are merely described based on a direction shown in drawings.

It will be further understood that the terms “comprises”, “includes”, “have”, etc. specify the presence of stated features, numbers, steps, operations, elements, components, or a combination thereof but do not preclude the presence or addition of one or more other features, numbers, steps, operations, elements, components, or a combination thereof.

Unless otherwise defined, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within 30%, 20%, 10%, 5% of the stated value.

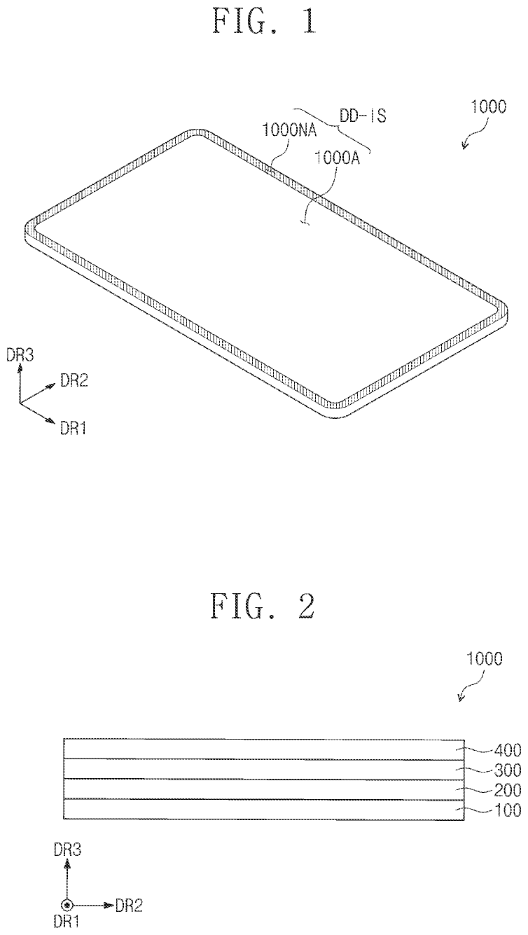

FIG. 1 is a schematic perspective view of a display device 1000 according to an embodiment of the disclosure.

Referring to FIG. 1, the display device 1000 may refer to a device that may be activated depending on an electrical signal. For example, the display device 1000 may be a cellular phone, a tablet, a car navigation system, a game console, a wearable device, a television, and/or a monitor, but is not limited specifically thereto.

The display device 1000 may display an image through a display surface DD-IS. The display surface DD-IS may be parallel to a surface that may be defined by a first direction DR1 and a second direction DR2. An upper surface of a member that may be disposed on the uppermost side (or layer) of the display device 1000 may be defined as the display surface DD-IS. A normal direction of the display surface DD-IS, for example, a thicknesses direction of the display device 1000 may correspond to a third direction DR3. A front surface (or an upper surface) and a back surface (or a lower surface) of each layer or unit may be divided with respect to the third direction DR3.

A display area 1000A and a non-display area 1000NA may be defined in the display device 1000. The non-display area 1000NA may be a surrounding area of the display area 1000A. The display device 1000 may display an image through the display area 1000A. The non-display area 1000NA may surround the display area 1000A. According to an embodiment of the disclosure, the non-display area 1000NA may be omitted or may be disposed only on a side of the display area 1000A. An example in which the display device 1000 may be planar is illustrated in FIG. 1, but the display device 1000 may be in a curved shape.

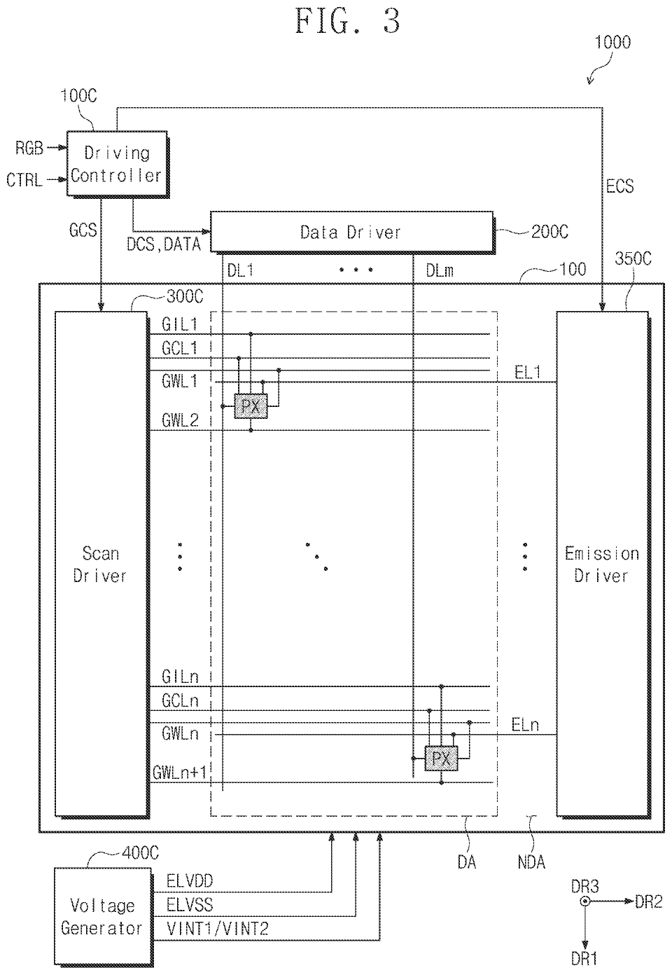

FIG. 2 is a schematic cross-sectional view of the display device 1000 according to an embodiment of the disclosure.

Referring to FIG. 2, the display device 1000 may include a display panel 100, a sensor layer 200, an optical film 300, and a window 400. According to an embodiment of the disclosure, some of the above components may be omitted, and any other components may be further added. An adhesive layer may be disposed between the members if necessary. The adhesive layer may include an optically clear adhesive (OCA) or a pressure sensitive adhesive film (PSA), but is not specifically limited thereto. Adhesive layers to be described below may include the above material or a typical adhesive agent.

The display panel 100 may be a component that substantially generates an image. The display panel 100 may be a light emitting display panel. For example, the display panel 100 may be an organic light emitting display panel, an inorganic light emitting display panel, an organic-inorganic light emitting display panel, a quantum dot display panel, a micro-LED display panel, or a nano-LED display panel.

The sensor layer 200 may be disposed on the display panel 100. The sensor layer 200 may detect (or sense) an external input that may be applied from the outside. The external input may be an input of a user. The user input may include various types of external inputs such as a part of a body of the user, a light, a heat, a pen, or a pressure.

The sensor layer 200 may be formed on the display panel 100 through a successive process. In this case, the sensor layer 200 may be expressed as being directly disposed on the display panel 100. The expression “being directly disposed” may mean that a third component is not disposed between the sensor layer 200 and the display panel 100. For example, a separate adhesive member may not be disposed between the sensor layer 200 and the display panel 100. Alternatively, the sensor layer 200 may be coupled to the display panel 100 through an adhesive member. The adhesive member may include a typical adhesive or a sticking agent. According to an embodiment of the disclosure, the sensor layer 200 may be omitted.

The optical film 300 may reduce a reflectance of a light incident from the outside. The optical film 300 may include a retarder and/or a polarizer. The optical film 300 may be referred to as a “polarizing film”. The optical film 300 may be attached to the sensor layer 200 through an adhesive layer.

Alternatively, the optical film 300 may include color filters. The color filters may have a given arrangement. The arrangement of the color filters may be determined in consideration of colors of lights generated from pixels included in the display panel 100. The optical film 300 may further include a black matrix adjacent to the color filters.

Alternatively, the optical film 300 may be a destructive interference structure. For example, the destructive interference structure may include a first reflective layer and a second reflective layer that may be disposed on different layers. The destructive interference may take place between a first reflected light and a second reflected light respectively reflected from the first reflective layer and the second reflective layer, and thus, the reflectance of the external light may be reduced.

The window 400 may be disposed on the optical film 300. The window 400 may include an optically transparent material. For example, the window 400 may include glass or plastic. The window 400 may have a multilayer structure or a single-layer structure. For example, the window 400 may include plastic films coupled by an adhesive or may have a glass substrate and a plastic film coupled by an adhesive.

FIG. 3 is a schematic block diagram of a display device according to an embodiment of the disclosure.

Referring to FIG. 3, the display device 1000 may include the display panel 100, a panel driver, and a driving controller 100C. As an example of the disclosure, the panel driver may include a data driver 200C, a scan driver 300C, an emission driver 350C, and a voltage generator 400C.

The driving controller 100C may receive an image signal RGB and a control signal CTRL. The driving controller 100C may generate an image data signal DATA by converting a data format of the image signal RGB in compliance with the specification for an interface with the data driver 200C. The driving controller 100C may output a first control signal GCS, a second control signal ECS, and a third control signal DCS.

The data driver 200C may receive the third control signal DCS and the image data signal DATA from the driving controller 100C. The data driver 200C may convert the image data signal DATA into data signals and outputs the data signals to data lines DL1 to DLm to be described later. The data signals may refer to analog voltages corresponding to a gray scale value of the image data signal DATA.

The scan driver 300C may receive the first control signal GCS from the driving controller 100C. The scan driver 300C may output scan signals to scan lines in response to the first control signal GCS.

The voltage generator 400C may generate voltages necessary for an operation of the display panel 100. In this embodiment, the voltage generator 400C may generate a first driving voltage ELVDD, a second driving voltage ELVSS, a first initialization voltage VINT1, and a second initialization voltage VINT2.

The display panel 100 may include a display area DA and a non-display area NDA. The display panel 100 may include pixels PX disposed in the display area DA. The pixels PX may be arranged based on a given rule.

The display panel 100 may further include the data lines DL1 to DLm, the scan lines, and emission control lines EL1 to ELn. The scan lines may include initialization scan lines GIL1 to GILn, compensation scan lines GCL1 to GCLn, and write scan lines GWL1 to GWLn.

The data lines DL1 to DLm may extend in the first direction DR1 and may be arranged to be spaced from each other in the second direction DR2. The initialization scan lines GIL1 to GILn, the compensation scan lines GCL1 to GCLn, the write scan lines GWL1 to GWLn, and the emission control lines EL1 to ELn may extend in the second direction DR2. The initialization scan lines GIL1 to GILn, the compensation scan lines GCL1 to GCLn, the write scan lines GWL1 to GWLn, and the emission control lines EL1 to ELn may be arranged to be spaced from each other in the first direction DR1.

The pixels PX may be electrically connected to the initialization scan lines GIL1 to GILn, the compensation scan lines GCL1 to GCLn, the write scan lines GWL1 to GWLn, the emission control lines EL1 to ELn, and the data lines DL1 to DLm. Each of the pixels PX may be electrically connected with (to) four scan lines. For example, as illustrated in FIG. 3, the pixels PX in the first row may be connected with the first initialization scan line GIL1, the first compensation scan line GCL1, the first write scan line GWL1, and the second write scan line GWL2. The pixels PX in the n-th row may be connected with the n-th second initialization scan line GILn, the n-th compensation scan line GCLn, the n-th write scan line GWLn, and the (n+1)-th write scan line GWLn+1. However, the above description is only an example, and the connection relationship between the pixels PX and the initialization scan lines GIL1 to GILn, the compensation scan lines GCL1 to GCLn, the write scan lines GWL1 to GWLn, the emission control lines EL1 to ELn, and the data lines DL1 to DLm is not limited to the example of FIG. 3.

The scan driver 300C may be disposed in the non-display area NDA of the display panel 100. The scan driver 300C may receive the first control signal GCS from the driving controller 100C. In response to the first control signal GCS, the scan driver 300C may output initialization scan signals to the initialization scan lines GIL1 to GILn and outputs compensation scan signals to the compensation scan lines GCL1 to GCLn. The scan driver 300C may output write scan signals to the write scan lines GWL1 to GWLn in response to the first control signal GCS. Alternatively, the scan driver 300C may include a first scan driver and a second scan driver. The first scan driver may output the initialization scan signals and the compensation scan signals, and the second scan driver may output the write scan signals.

The emission driver 350C may be disposed in the non-display area NDA of the display panel 100. The emission driver 350C may receive the second control signal ECS from the driving controller 100C. The emission driver 350C may output emission control signals to the emission control lines EL1 to ELn in response to the second control signal ECS. Alternatively, the scan driver 300C may be connected with the emission control lines EL1 to ELn. In this case, the scan driver 300C may output the emission control signals to the emission control lines EL1 to ELn.

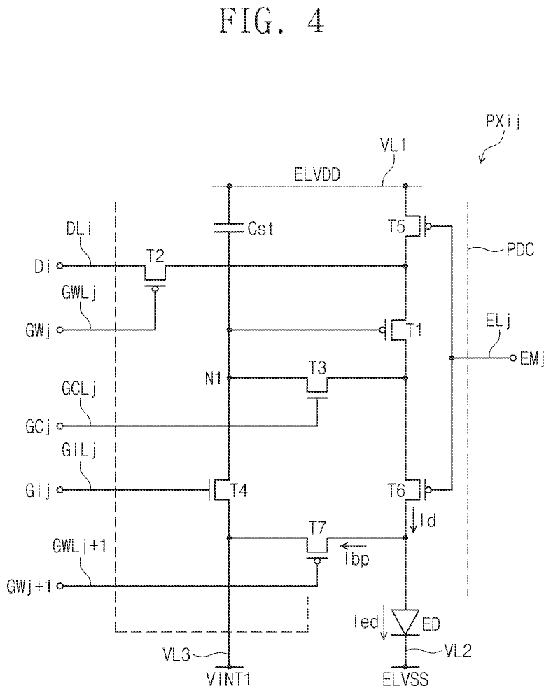

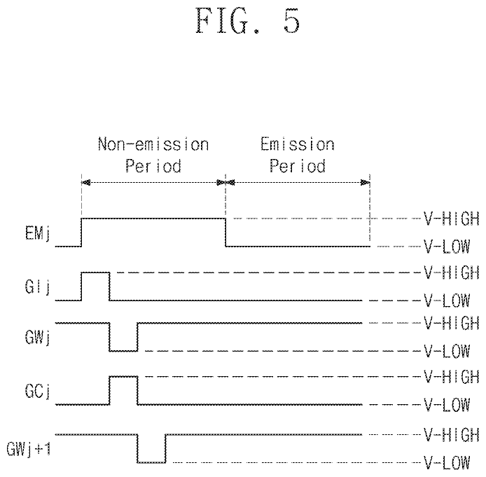

FIG. 4 is a schematic circuit diagram illustrating a pixel according to an embodiment of the disclosure. FIG. 5 is a schematic waveform diagram of driving signals for driving a pixel illustrated in FIG. 4.

An equivalent circuit diagram of a pixel PXij of the pixels PX illustrated in FIG. 3 is illustrated in FIG. 4 as an example. Below, a circuit structure of the pixel PXij will be described. The pixels PX may have the same structure, and thus, additional description associated with the remaining pixels other than the pixel PXij will be omitted to avoid redundancy.

Referring to FIGS. 4 and 5, the pixel PXij is connected with the i-th data line DLi of the data lines DL1 to DLm, the j-th initialization scan line GILj of the initialization scan lines GIL1 to GILn, the j-th compensation scan line GCLj of the compensation scan lines GCL1 to GCLn, the j-th write scan line GWLj of the write scan lines GWL1 to GWLn, the (j+1)-th write scan line GWLj+1 of the write scan lines GWL1 to GWLn, and the j-th emission control line ELj of the emission control lines EL1 to ELn.

The pixel PXij may include a light emitting element ED and a pixel driving circuit PDC. The light emitting element ED may be a light emitting diode. As an example of the disclosure, the light emitting element ED may be an organic light emitting diode including an organic emission layer.

The pixel driving circuit PDC may include first to seventh transistors T1, T2, T3, T4, T5, T6, and T7 and a storage capacitor Cst. The first to seventh transistors T1, T2, T3, T4, T5, T6, and T7 may be respectively referred to as the “driving thin film transistor T1”, the “switching thin film transistor T2”, the “compensation thin film transistor T3”, the “first initialization thin film transistor T4”, the “operation control thin film transistor T5”, the “emission control thin film transistor T6”, and the “second initialization thin film transistor T7”.

Some of the first to seventh transistors T1 to T7 may be P-type transistors, and the remaining transistors may be N-type transistors. For example, the first, second, fifth, sixth, and seventh transistors T1, T2, T5, T6, and T7 may be PMOS transistors, and the third and fourth transistors T3 and T4 may be NMOS transistors.

At least one of the first to seventh transistors T1, T2, T3, T4, T5, T6, and T7 may be a transistor having a low-temperature polycrystalline silicon (LTPS) semiconductor layer, and at least one of the remaining first to seventh transistors T1, T2, T3, T4, T5, T6, and T7 may be a transistor having an oxide semiconductor layer.

In detail, the first transistor T1 having a direct influence on brightness of a display device may be configured to include a semiconductor layer formed of a polycrystalline silicon having high reliability, and thus, a high-resolution display device may be implemented.

However, because the oxide semiconductor has a high carrier mobility and a low leakage current, the voltage drop may be not significant even though the driving time is long. For example, even during low-frequency driving, the color of the image may not be significantly changed by the voltage drop. Accordingly, the low-frequency driving may be possible. As described above, because a leakage current of the oxide semiconductor may be small, at least one of the third transistor T3 and the fourth transistor T4 connected with a driving gate electrode of the first transistor T1 may be implemented with the oxide semiconductor, thus preventing the leakage current capable of flowing into the driving gate electrode and reducing power consumption.

The first, second, fifth, sixth, and seventh transistors T1, T2, T5, T6, and T7 may be transistors having the low-temperature polycrystalline silicon semiconductor layer, and the third and fourth transistors T3 and T4 may be transistors having the oxide semiconductor layer.

A configuration of the pixel driving circuit PDC according to the disclosure is not limited to the embodiment illustrated in FIG. 4. The pixel driving circuit PDC illustrated in FIG. 4 is only an example, and the configuration of the pixel driving circuit PDC may be modified and implemented. For example, all the first to seventh transistors T1 to T7 may be P-type transistors or N-type transistors.

The j-th initialization scan line GILj, the j-th compensation scan line GCLj, the j-th write scan line GWLj, the (j+1)-th write scan line GWLj+1, and the j-th emission control line ELj may transfer a j-th initialization scan signal GIj, a j-th compensation scan signal GCj, a j-th write scan signal GWj, a (j+1)-th write scan signal GWj+1, and a j-th emission control signal EMj to the pixel PXij, respectively. The i-th data line DLi transfers an i-th data signal Di to the pixel PXij. The i-th data signal Di may have a voltage level corresponding to the image signal RGB (refer to FIG. 3) input to the display device 1000 (refer to FIG. 3).

A first driving voltage line VL1 and a second driving voltage line VL2 may respectively transfer the first driving voltage ELVDD and the second driving voltage ELVSS to the pixel PXij. A first initialization voltage line VL3 may transfer the first initialization voltage VINT1 to the pixel PXij.

The first transistor T1 may be connected between the first driving voltage line VL1 receiving the first driving voltage ELVDD and the light emitting element ED. The first transistor T1 may include a first electrode connected with the first driving voltage line VL1 through the fifth transistor T5, a second electrode electrically connected with an anode of the light emitting element ED through the sixth transistor T6, and a third electrode connected to one end of the storage capacitor Cst. The first transistor T1 may receive the i-th data signal Di transferred through the i-th data line DLi depending on a switching operation of the second transistor T2 and then may supply a driving current Id to the light emitting element ED.

The second transistor T2 may be connected between the i-th data line DLi and the first electrode of the first transistor T1. The second transistor T2 may include a first electrode connected with the i-th data line DLi, a second electrode connected with the first electrode of the first transistor T1, and a third electrode connected with the j-th write scan line GWLj. The second transistor T2 may be turned on depending on the j-th write scan signal GWj transferred through the j-th write scan line GWLj and then may transfer the i-th data signal Di transferred from the i-th data line DLi to the first electrode of the first transistor T1.

The third transistor T3 may be connected between the second electrode of the first transistor T1 and a first node N1. The third transistor T3 may include a first electrode connected with the third electrode of the first transistor T1, a second electrode connected with the second electrode of the first transistor T1, and a third electrode connected with the j-th compensation scan line GCLj. The third transistor T3 may be turned on depending on the j-th compensation scan signal GCj transferred through the j-th compensation scan line GCLj and may connect the third electrode and the second electrode of the first transistor T1 such that the first transistor T1 is diode-connected.

The fourth transistor T4 may be connected between the first initialization voltage line VL3 to which the first initialization voltage VINT1 may be applied and the first node N1. The fourth transistor T4 may include a first electrode connected with the third electrode of the first transistor T1, a second electrode connected with the first initialization voltage line VL3 through which the first initialization voltage VINT1 may be transferred, and a third electrode connected with the j-th initialization scan line GILj. The fourth transistor T4 may be turned on depending on the j-th initialization scan signal GIj transferred through the j-th initialization scan line GILj. The fourth transistor T4 thus turned on may transfer the first initialization voltage VINT1 to the third electrode of the first transistor T1 such that a potential of the third electrode of the first transistor T1 (i.e., a potential of the first node N1) may be initialized.

The fifth transistor T5 may include a first electrode connected with the first driving voltage line VL1, a second electrode connected with the first electrode of the first transistor T1, and a third electrode connected with the j-th emission control line ELj.

The sixth transistor T6 may include a first electrode connected with the second electrode of the first transistor T1, a second electrode connected with the anode of the light emitting element ED, and a third electrode connected with the j-th emission control line ELj.

The fifth and sixth transistors T5 and T6 may be simultaneously turned on depending on the j-th emission control signal EMj transferred through the j-th emission control line ELj. The first driving voltage ELVDD applied through the turned-on fifth transistor T5 may be transferred to the light emitting element ED after compensated through the diode-connected first transistor T1.

The seventh transistor T7 may include a first electrode connected with the first initialization voltage line VL3 to which the first initialization voltage VINT1 is applied, a second electrode connected with the second electrode of the sixth transistor T6, and a third electrode connected with the (j+1)-th write scan line GWLj+1. As an example of the disclosure, the first initialization voltage VINT1 may be a negative constant voltage. For example, the first initialization voltage VINT1 may be a voltage of −3.5 V, but is not specifically limited thereto.

As described above, the first electrode of the storage capacitor Cst may be connected with the third electrode of the first transistor T1, and a second electrode of the storage capacitor Cst is connected with the first driving voltage line VL1. A cathode of the light emitting element ED may be connected with the second driving voltage line VL2 transferring the second driving voltage ELVSS. A voltage level of the second driving voltage ELVSS may be lower than a voltage level of the first driving voltage ELVDD. As an example of the disclosure, a voltage level of the second driving voltage ELVSS may be lower than a voltage level of the first initialization voltage VINT1.

During an active period of the j-th initialization scan signal GIj, in case that the j-th initialization scan signal GIj of a high level (V-HIGH) is provided through the j-th initialization scan line GILj, the fourth transistor T4 may be turned on in response to the j-th initialization scan signal GIj of the high level. The first initialization voltage VINT1 is transferred to the third electrode of the first transistor T1 through the fourth transistor T4 thus turned on, and the first node N1 is initialized to the first initialization voltage VINT1. Accordingly, the active period of the j-th initialization scan signal GIj may be an initialization period of the pixel PXij.

Next, the j-th compensation scan signal GCj may be activated, and during an active period of the j-th compensation scan signal GCj, the third transistor T3 may be turned on in case that the j-th compensation scan signal GCj of the high level is supplied through the j-th compensation scan line GCLj. The first transistor T1 may be diode-connected by the third transistor T3 thus turned on so as to be forward-biased.

The j-th write scan signal GWj may be activated within the active period of the j-th compensation scan signal GCj. The j-th write scan signal GWj may have a low level (V-LOW) during an active period. During the active period of the j-th write scan signal GWj, the second transistor T2 is turned on by the j-th write scan signal GWj of the low level. In this case, a compensation voltage may be applied to the third electrode of the first transistor T1. Herein, the compensation voltage may correspond to a result of subtracting a threshold voltage of the first transistor T1 from a voltage of the i-th data signal Di supplied from the i-th data line DLi. For example, a potential of the third electrode of the first transistor T1 may be the compensation voltage.

The first driving voltage ELVDD and the compensation voltage may be respectively applied to opposite ends of the storage capacitor Cst, and charges corresponding to a voltage difference of the opposite ends of the storage capacitor Cst may be stored in the storage capacitor Cst. Herein, a high level period of the j-th compensation scan signal GCj may be referred to as a “compensation period” of the pixel PXij.

The (j+1)-th write scan signal GWj+1 may be activated. The (j+1)-th write scan signal GWj+1 may have the low level during an active period. The seventh transistor T7 may be turned on during the active period of the (j+1)-th write scan signal GWj+1. A portion of the driving current Id may be drained through the seventh transistor T7 as a bypass current Ibp.

In case that the light emitting element ED emits a light under the condition that a minimum current of the first transistor T1 displaying a black image flows as a driving current, the black image is not displayed normally. Accordingly, the seventh transistor T7 of the pixel PXij according to an embodiment of the disclosure may drain a portion of the minimum current of the first transistor T1 to a current path, which may be different from a current path to the light emitting element ED, as the bypass current Ibp. Herein, the minimum current of the first transistor T1 may mean a current flowing under the condition that a gate-source voltage of the first transistor T1 may be smaller than the threshold voltage, for example, under the condition that the first transistor T1 may be turned off. As a minimum driving current (e.g., a current of 10 pA or less) is transferred to the light emitting element ED, with the first transistor T1 turned off, an image of black luminance may be expressed. In case that the minimum driving current for displaying a black image flows, the influence of a bypass transfer of the bypass current Ibp may be great; in contrast, in case that a large driving current for displaying an image such as a normal image or a white image flows, there may be almost no influence of the bypass current Ibp. Accordingly, in case that a driving current for displaying a black image flows, a light emitting current led of the light emitting element ED, which corresponds to a result of subtracting the bypass current Ibp drained through the seventh transistor T7 from the driving current Id, may have a minimum current amount to such an extent as to accurately express a black image. Accordingly, a contrast ratio may be improved by implementing an accurate black luminance image by using the seventh transistor T7.

Next, the j-th emission control signal EMj that may be supplied from the j-th emission control line ELj transitions from the high level to the low level. The fifth and sixth transistors T5 and T6 may be turned on by the emission control signal EMj of the low level. In this case, the driving current Id may be generated depending on a difference between the voltage of the third electrode of the first transistor T1 and the first driving voltage ELVDD. The driving current Id thus generated may be supplied to the light emitting element ED through the sixth transistor T6, and thus, the current led flows through the light emitting element ED.

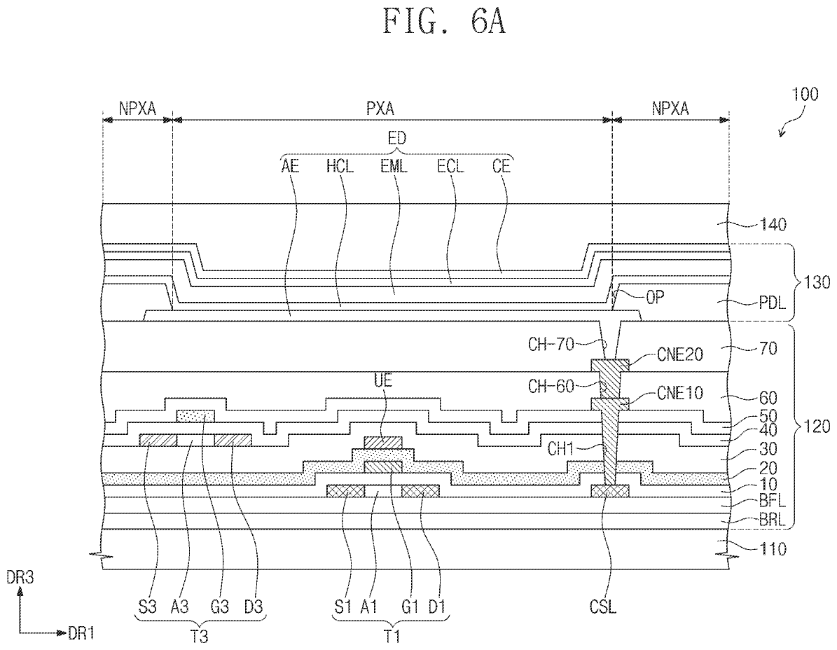

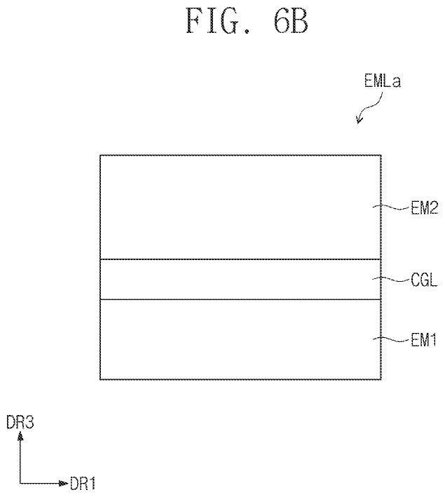

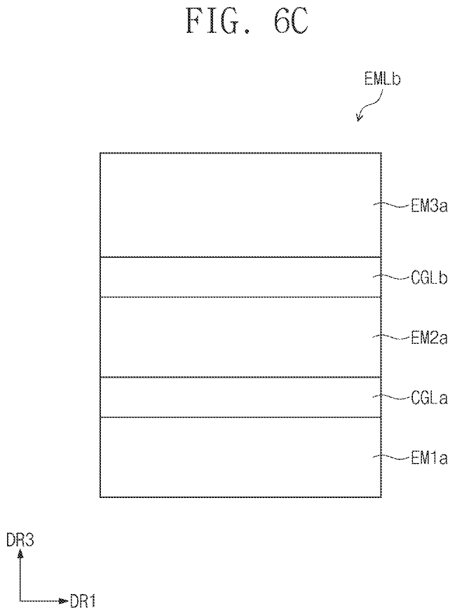

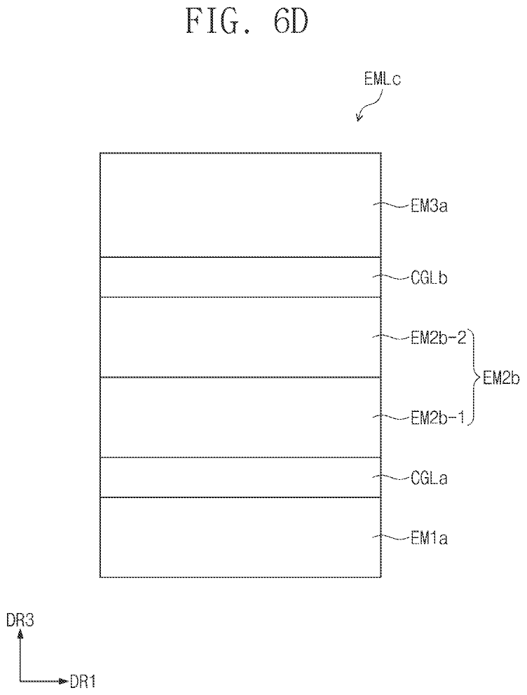

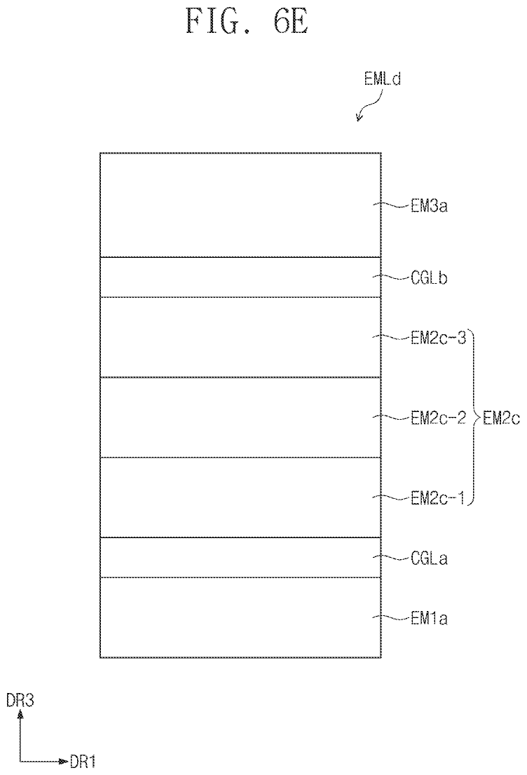

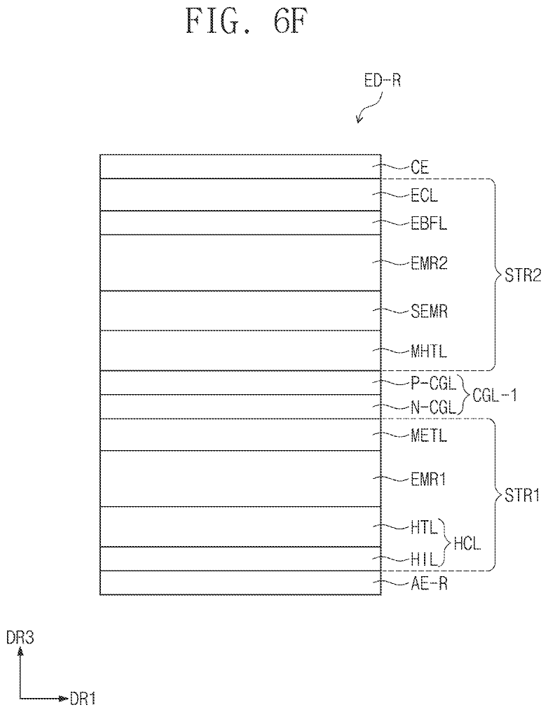

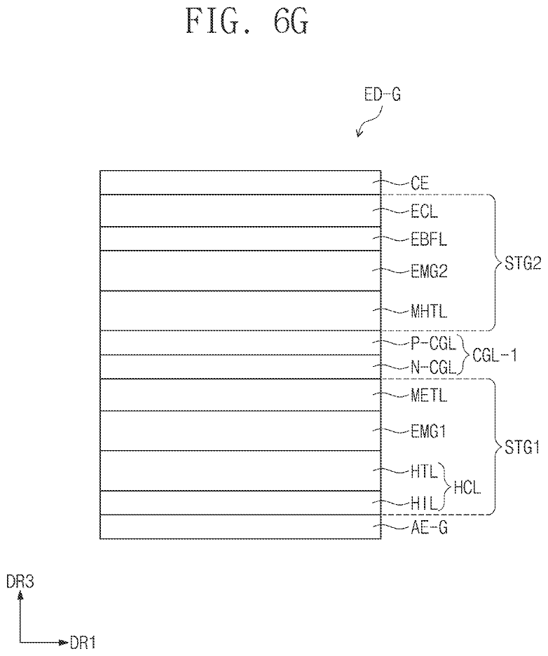

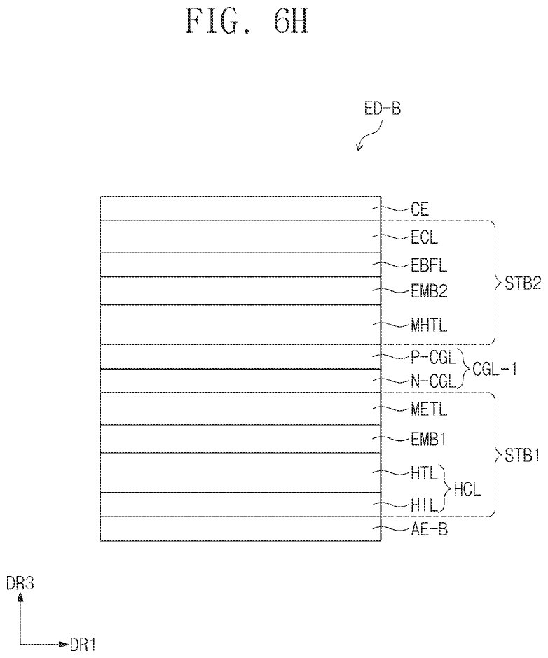

FIG. 6A is a schematic cross-sectional view illustrating a pixel of a display panel according to an embodiment of the disclosure.

Referring to FIG. 6A, the display panel 100 may include a substrate 110, a circuit layer 120 disposed on the substrate 110, an element layer 130, and an encapsulation layer 140.

The substrate 110 may be a member that provides a base surface on which the circuit layer 120 may be disposed. The substrate 110 may be a rigid substrate, or a flexible substrate allowing bending, folding, or rolling. The substrate 110 may be a glass substrate, a metal substrate, or a polymer substrate. However, the embodiment is not limited thereto, but the substrate 110 may be an inorganic layer, an organic layer, or a composite material layer.

The substrate 110 may have a multilayer structure. For example, the substrate 110 may include a first synthetic resin layer, an intermediate layer in a multilayer structure or a single-layer structure, and a second synthetic resin layer disposed on the intermediate layer. The intermediate layer may be referred to as a base barrier layer. The intermediate layer may include a silicon oxide (SiOₓ) layer and an amorphous silicon (a-Si) layer disposed on the silicon oxide layer, but is not specifically limited thereto. For example, the intermediate layer may include at least one of a silicon oxide layer, a silicon nitride layer, a silicon oxynitride layer, and an amorphous silicon layer.

Each of the first and second synthetic resin layers may include polyimide-based resin. Each of the first and second synthetic resin layers may include at least one of acrylate-based resin, methacrylate-based resin, polyisoprene-based resin, vinyl-based resin, epoxy-based resin, urethane-based resin, cellulose-based resin, siloxane-based resin, polyamide-based resin, and perylene-based resin. The expression “˜˜-based resin” may include the meaning the functional group of “˜˜”.

At least one inorganic layer may be formed on an upper surface of the substrate 110. The inorganic layer may include at least one of aluminum oxide, titanium oxide, silicon oxide, silicon oxynitride, zirconium oxide, and hafnium oxide. The inorganic layer may be formed of multiple layers. The multiple inorganic layers may constitute a barrier layer BRL and/or a buffer layer BFL, which will be described later. The barrier layer BRL and the buffer layer BFL may be disposed selectively.

The barrier layer BRL may prevent foreign objects from being introduced from the outside. The barrier layer BRL may include a silicon oxide layer and a silicon nitride layer. Each of the silicon oxide layer and the silicon nitride layer may include layers, and the silicon oxide layers and the silicon nitride layers may be alternately stacked on each other.

The buffer layer BFL may be disposed on the barrier layer BRL. The buffer layer BFL may improve a bonding force between the substrate 110 and a semiconductor pattern and/or a conductive pattern. The buffer layer BFL may include a silicon oxide layer and a silicon nitride layer. The silicon oxide layer and the silicon nitride layer may be alternately stacked on each other.

A semiconductor pattern may be disposed on the buffer layer BFL. Below, a semiconductor pattern directly disposed on the buffer layer BFL may be defined as a first semiconductor pattern. The first semiconductor pattern may include a silicon semiconductor. The first semiconductor pattern may include polysilicon. However, the disclosure is not limited thereto. For example, the first semiconductor pattern may include amorphous silicon.

FIG. 6A shows only a part of the first semiconductor pattern disposed on the buffer layer BFL, and the first semiconductor pattern may be further disposed in the remaining area of the pixel PXij (refer to FIG. 5). The first semiconductor pattern may be arranged across the pixels based on a specific rule. An electrical property of the first semiconductor pattern may vary depending on whether it is doped. The first semiconductor pattern may include a first area whose conductivity may be high and a second area whose conductivity may be low. The first area may be doped with an N-type dopant or a P-type dopant. A P-type transistor may include a doping area doped with the P-type dopant, and an N-type transistor may include a doping area doped with the N-type dopant. The second area may be a non-doping area or may be an area doped with a lower concentration than the first area.

The conductivity of the first area may be higher than the conductivity of the second area, and the first area may substantially serve as an electrode or a signal line. The second area may substantially correspond to an active area (or channel) of a transistor. In other words, a portion of the first semiconductor pattern may be an active area of a transistor, another portion of the first semiconductor pattern may be a source area or a drain area of the transistor, and another portion of the semiconductor pattern may be a connection electrode or a connection signal line.

As illustrated in FIG. 6A, a first electrode Si, a channel A1, and a second electrode D1 of the first transistor T1 may be formed from the first semiconductor pattern. The first electrode Si and the second electrode D1 of the first transistor T1 may extend from the channel A1 in opposite directions.

A portion of a connection signal line CSL formed from the semiconductor pattern is illustrated in FIG. 6A. Although not illustrated separately, the connection signal line CSL may be electrically connected with the second electrode of the sixth transistor T6 (refer to FIG. 4) in a plan view.

A first insulating layer 10 may be disposed on the buffer layer BFL. The first insulating layer 10 may overlap multiple pixels in common and may cover the first semiconductor pattern. The first insulating layer 10 may be an inorganic layer and/or an organic layer, and may have a single-layer or multilayer structure. The first insulating layer 10 may include at least one of aluminum oxide, titanium oxide, silicon oxide, silicon nitride, silicon oxynitride, zirconium oxide, and hafnium oxide. In this embodiment, the first insulating layer 10 may be a single silicon oxide layer. As well as the first insulating layer 10, an insulating layer of the circuit layer 120 to be described later may be an inorganic layer and/or an organic layer, and may have a single-layer or multilayer structure. The inorganic layer may include at least one of the materials described above but is not limited thereto.

A third electrode G1 of the first transistor T1 may be disposed on the first insulating layer 10. The third electrode G1 may be a portion of a first conductive pattern. The third electrode G1 of the first transistor T1 may overlap the channel A1 of the first transistor T1. The third electrode G1 of the first transistor T1 may serve as a mask in the process of doping the first semiconductor pattern.

A second insulating layer 20 may be disposed on the first insulating layer 10 and may cover the third electrode G1 of the first transistor T1. The second insulating layer 20 may be an inorganic layer and/or an organic layer, and may have a single-layer structure or a multilayer structure. The second insulating layer 20 may include at least one of silicon oxide, silicon nitride, and silicon oxynitride. In this embodiment, the second insulating layer 20 may have a multilayer structure including a silicon oxide layer and a silicon nitride layer.

A third insulating layer 30 may be disposed on the second insulating layer 20. The third insulating layer 30 may have a single-layer or multilayer structure. For example, the third insulating layer 30 may have a multilayer structure including a silicon oxide layer and a silicon nitride layer. An upper electrode UE of the storage capacitor Cst may be disposed between the second insulating layer 20 and the third insulating layer 30. A lower electrode of the storage capacitor Cst may be disposed between the first insulating layer 10 and the second insulating layer 20.

According to an embodiment of the disclosure, the second insulating layer 20 may be replaced with an insulating pattern. The upper electrode UE may be disposed on the insulating pattern. The upper electrode UE may serve as a mask for forming the insulating pattern from the second insulating layer 20.

A second semiconductor pattern may be disposed on the third insulating layer 30. The second semiconductor pattern may include an oxide semiconductor. The oxide semiconductor may include areas that may be distinguished depending on whether the metal oxide is reduced. An area (hereinafter referred to as a “reduction area”) in which the metal oxide may be reduced may have higher conductivity than an area (hereinafter referred to as a “non-reduction area”) in which the metal oxide may not be reduced. The reduction area may substantially serve as a source/drain of a transistor or a signal line. The non-reduction area may substantially correspond to an active area (or a semiconductor area or a channel area) of a transistor. In other words, a portion of the semiconductor pattern may be an active area of a transistor, another portion thereof may be a source area or a drain area of the transistor, and another portion may be a connection electrode or a connection signal line.

As illustrated in FIG. 6A, a first electrode S3, a channel A3, and a second electrode D3 of the third transistor T3 may be formed from the second semiconductor pattern. The first electrode S3 and the second electrode D3 may include a metal reduced from a metal oxide semiconductor. The first electrode S3 and the second electrode D3 may include a metal layer that has a given thickness from an upper surface of the second semiconductor pattern and include the reduced metal.

A fourth insulating layer 40 may be disposed on the third insulating layer 30. The fourth insulating layer 40 may overlap the pixels in common and may cover the second semiconductor pattern. The fourth insulating layer 40 may include at least one of aluminum oxide, titanium oxide, silicon oxide, silicon nitride, silicon oxynitride, zirconium oxide, and a hafnium oxide.

A third electrode G3 of the third transistor T3 may be disposed on the fourth insulating layer 40. The third electrode G3 may be a portion of a third conductive pattern. The third electrode G3 of the third transistor T3 may overlap the channel A3 of the third transistor T3. The third electrode G3 of the third transistor T3 may serve as a mask in the process of doping the second semiconductor pattern.

In an embodiment of the disclosure, the fourth insulating layer 40 may be replaced with an insulating pattern. The third electrode G3 of the third transistor T3 may be disposed on the insulating pattern. In this embodiment, the third electrode G3 may have the same shape as the insulating pattern in a plan view. In an embodiment, for convenience of description, one third electrode G3 is illustrated, but the third transistor T3 may include two third electrodes.

A fifth insulating layer 50 may be disposed on the fourth insulating layer 40 and may cover the third electrode G3 of the third transistor T3. The fifth insulating layer 50 may be an inorganic layer and/or an organic layer, and may have a single-layer structure or a multilayer structure. For example, the fifth insulating layer 50 may include a silicon oxide layer and a silicon nitride layer. The fifth insulating layer 50 may include silicon oxide layers and silicon nitride layers, which may be alternately stacked on each other.

Although not illustrated separately, the first electrode and the second electrode of the fourth transistor T4 (refer to FIG. 4) may be formed through the same process as the first electrode S3 and the second electrode D3 of the third transistor T3.

A first connection electrode CNE10 may be disposed on the fifth insulating layer 50. The first connection electrode CNE10 may be connected with the connection signal line CSL through a contact hole CHi penetrating the first to fifth insulating layers 10, 20, 30, 40, and 50.

A sixth insulating layer 60 may be disposed on the fifth insulating layer 50. A second connection electrode CNE20 may be disposed on the sixth insulating layer 60. The second connection electrode CNE20 may be connected with the first connection electrode CNE10 through a contact hole CH-60 penetrating the sixth insulating layer 60. A seventh insulating layer 70 may be disposed on the sixth insulating layer 60 and may cover the second connection electrode CNE20.

Each of the sixth insulating layer 60 and the seventh insulating layer 70 may be an organic layer. For example, each of the sixth insulating layer 60 and the seventh insulating layer 70 may include general purpose polymers such as benzocyclobutene (BCB), polyimide, hexamethyldisiloxane (HMDSO), polymethylmethacrylate (PMMA), or polystyrene (PS); a polymer derivative having a phenolic group; an acrylic polymer; an imide-based polymer; an acryl ether polymer; an amide-based polymer; a fluorine-based polymer; a p-xylene-based polymer; a vinyl alcohol-based polymer; or a blend thereof.

The element layer 130 may include the light emitting element ED and a pixel defining layer PDL. The light emitting element ED may include an anode AE, a hole control layer HCL, an emission layer EML, an electron control layer ECL, and a cathode CE.

The anode AE may be disposed on the seventh insulating layer 70. The anode AE may be connected with the second connection electrode CNE20 through a contact hole CH-70 penetrating the seventh insulating layer 70. The anode AE may be a (semi) light-transmitting electrode or a reflective electrode. In an embodiment, the anode AE may include a reflective layer formed of Ag, Mg, Al, Pt, Pd, Au, Ni, Nd, Ir, Cr, or a compound thereof, and a transparent or semi-transparent electrode layer formed on the reflective layer. The transparent or semi-transparent electrode layer may include at least one or more selected from a group of indium tin oxide (ITO), indium zinc oxide (IZO), indium gallium zinc oxide (IGZO), zinc oxide (ZnO) or indium oxide (In₂O₃), and aluminum doped zinc oxide (AZO). For example, the anode AE may be formed of ITO/Ag/ITO.

The pixel defining layer PDL may be disposed on the seventh insulating layer 70. In an embodiment, the pixel defining layer PDL may have a property of absorbing a light, for example, the pixel defining layer PDL may have a black color. The pixel defining layer PDL may include a black coloring agent. The black coloring agent may include a black dye and a black pigment. The black coloring agent may include carbon black, aniline black, a metal such as chrome, an oxide thereof, or a combination thereof. The pixel defining layer PDL may be formed by mixing a blue organic material and a black organic material. The pixel defining layer PDL may further include a liquid-repellent organic material.

An opening OP of the pixel defining layer PDL may expose at least a portion of the anode AE of the light emitting element ED. The opening OP of the pixel defining layer PDL may define an emission area PXA. For example, the pixels PX (refer to FIG. 3) may be arranged on a plane of the display panel 100 (refer to FIG. 3) depending on a specific rule. An area in which the pixels PX may be arranged may be defined as a pixel area, and a pixel area may include the emission area PXA and a non-emission area NPXA adjacent to the emission area PXA. The non-emission area NPXA may surround the emission area PXA.

The hole control layer HCL may be disposed in common in the emission area PXA and the non-emission area NPXA. A common layer such as the hole control layer HCL may be formed in common in the pixels PX. The hole control layer HCL may include a hole transport layer and a hole injection layer.

The emission layer EML may be disposed on the hole control layer HCL. The emission layer EML may be disposed in common in the pixels PX. For example, the emission layer EML may be disposed in common in the emission area PXA and the non-emission area NPXA. For example, the emission layer EML may be formed in common in the whole of the emission area PXA and the non-emission area NPXA by an open mask. In this case, the emission layer EML may generate a source light of a white light or a blue light. The emission layer EML may have a multilayer structure.

The display device 1000 (refer to FIG. 2) may further include a light control layer controlling a color of the source light. For example, the light control layer may be provided between the sensor layer 200 (refer to FIG. 2) and the optical film 300 (refer to FIG. 2). The light control layer may convert an optical property of the source light generated in the emission layer EML. The light control layer may include a light conversion pattern converting the source light into a light of any other color, and a scattering pattern scattering the source light. Alternatively, only a color corresponding to each of color filters may be passed by the optical film 300 (refer to FIG. 2) including the color filters without the light control layer.

According to an embodiment of the disclosure, the emission layer EML may be disposed only in an area corresponding to the opening OP. In this case, the emission layer EML may include emission layers, each of which may be formed for each of the pixels PX. The emission layers EML may generate a source light of a white light or a blue light. Alternatively, some of the emission layers EML may generate a red light, others thereof may generate a green light, and the others thereof may generate a blue light. However, the above description is only an example, and some of the emission layers EML may be a mixed color light, for example, a magenta light, a yellow light, or a cyan light.

The electron control layer ECL may be disposed on the emission layer EML. The electron control layer ECL may include an electron transport layer and an electron injection layer. The cathode CE of the light emitting element ED may be disposed on the electron control layer ECL. The electron control layer ECL and the cathode CE may be disposed in common in the pixels PX.

The encapsulation layer 140 may be disposed on the cathode CE. The encapsulation layer 140 may cover the pixels PX. In this embodiment, the encapsulation layer 140 may directly cover the cathode CE. According to an embodiment of the disclosure, the display panel 100 may further include a capping layer directly covering the cathode CE. According to an embodiment of the disclosure, the stacked structure of the light emitting element ED may be vertically inverted in the structure illustrated in FIG. 6A.

The encapsulation layer 140 may be disposed on the element layer 130. The encapsulation layer 140 may include at least one inorganic layer or at least one organic layer. According to an embodiment of the disclosure, the encapsulation layer 140 may include two inorganic layers and an organic layer disposed therebetween. According to an embodiment of the disclosure, a thin-film encapsulation layer may include inorganic layers and organic layers, which may be alternately stacked on each other.

An encapsulation inorganic layer may protect the light emitting element ED from moisture or oxygen, and an encapsulation organic layer may protect the light emitting element ED from foreign objects such as dust particles. The encapsulation inorganic layer may include a silicon nitride layer, a silicon oxynitride layer, a silicon oxide layer, a titanium oxide layer, an aluminum oxide layer, or the like, or a combination thereof, but is not specifically limited. The encapsulation organic layer may include an acryl-based organic layer, and is not specifically limited.

FIG. 6B is a schematic cross-sectional view illustrating a stacked structure of an emission layer EMLa according to an embodiment of the disclosure.

Referring to FIG. 6B, the emission layer EMLa may be one kind of the emission layer EML illustrated in FIG. 6A. The emission layer EMLa may include a first sub-emission layer EM1, a charge generation layer CGL, and a second sub-emission layer EM2 that may be sequentially stacked on each other in the third direction DR3.

The first sub-emission layer EM1 and the second sub-emission layer EM2 may emit lights of different colors. For example, the first sub-emission layer EM1 and the second sub-emission layer EM2 may emit lights of complementary colors, respectively. For example, the first sub-emission layer EM1 may emit a blue light, and the second sub-emission layer EM2 may emit a yellow light. Accordingly, the emission layer EMLa may provide a source light of a white color corresponding to a combination of the light provided from the first sub-emission layer EM1 and the light provided from the second sub-emission layer EM2.

The charge generation layer CGL may be disposed between the first sub-emission layer EM1 and the second sub-emission layer EM2. The charge generation layer CGL may supply electrons or holes to the first sub-emission layer EM1 and the second sub-emission layer EM2 such that emission efficiency may be improved.

FIG. 6C is a schematic cross-sectional view illustrating a stacked structure of an emission layer EMLb according to an embodiment of the disclosure.

Referring to FIG. 6C, the emission layer EMLb may be one kind of the emission layer EML illustrated in FIG. 6A. The emission layer EMLb may include a first sub-emission layer EM1a, a first charge generation layer CGLa, a second sub-emission layer EM2a, a second charge generation layer CGLb, and a third sub-emission layer EM3a that may be sequentially stacked on each other in the third direction DR3.

At least one of the first sub-emission layer EM1a, the second sub-emission layer EM2a, and the third sub-emission layer EM3a may emit a light whose color may be different from that of a light emitted from at least one of the remaining sub-emission layers. For example, each of the first sub-emission layer EM1a and the third sub-emission layer EM3a may emit a first light of the same color, and the second sub-emission layer EM2a may emit a light whose color may be different from that of the first light. For example, the first light and the second light may be complementary. For example, each of the first sub-emission layer EM1a and the third sub-emission layer EM3a may emit a blue light, and the second sub-emission layer EM2a may emit a yellow light. Accordingly, the emission layer EMLb may provide a source light of a white color corresponding to a combination of the lights provided from the first sub-emission layer EM1a, the second sub-emission layer EM2a, and the third sub-emission layer EM3a.

The first charge generation layer CGLa may be disposed between the first sub-emission layer EM1a and the second sub-emission layer EM2a. The second charge generation layer CGLb may be disposed between the second sub-emission layer EM2a and the third sub-emission layer EM3a. The first charge generation layer CGLa may supply electrons or holes to the first sub-emission layer EM1a and the second sub-emission layer EM2a such that emission efficiency may be improved. The second charge generation layer CGLb may supply electrons or holes to the second sub-emission layer EM2a and the third sub-emission layer EM3a such that emission efficiency may be improved.

FIG. 6D is a schematic cross-sectional view illustrating a stacked structure of an emission layer EMLc according to an embodiment of the disclosure.

Referring to FIG. 6D, the emission layer EMLc may be one kind of the emission layer EML illustrated in FIG. 6A. The emission layer EMLc may include the first sub-emission layer EM1a, the first charge generation layer CGLa, a second sub-emission layer EM2b, the second charge generation layer CGLb, and the third sub-emission layer EM3a that may be sequentially stacked on each other in the third direction DR3.

The second sub-emission layer EM2b may include a (2-1)-th sub-emission layer EM2b-1 and a (2-2)-th sub-emission layer EM2b-2 that emit lights of different colors. The (2-1)-th sub-emission layer EM2b-1 and the (2-2)-th sub-emission layer EM2b-2 may contact each other. As the second sub-emission layer EM2b may include the (2-1)-th sub-emission layer EM2b-1 and the (2-2)-th sub-emission layer EM2b-2 emitting lights of different colors, the color purity of the emission layer EMLc may be further improved.

For example, the (2-1)-th sub-emission layer EM2b-1 may emit a red light, and the (2-2)-th sub-emission layer EM2b-2 may emit a yellow light. In an embodiment, the (2-1)-th sub-emission layer EM2b-1 may emit a green light, and the (2-2)-th sub-emission layer EM2b-2 may emit a yellow light. In an embodiment, the (2-1)-th sub-emission layer EM2b-1 may emit a yellow light, and the (2-2)-th sub-emission layer EM2b-2 may emit a red light. In an embodiment, the (2-1)-th sub-emission layer EM2b-1 may emit a yellow light, and the (2-2)-th sub-emission layer EM2b-2 may emit a green light.

FIG. 6E is a schematic cross-sectional view illustrating a stacked structure of an emission layer EMLd according to an embodiment of the disclosure.

Referring to FIG. 6E, the emission layer EMLd may be one kind of the emission layer EML illustrated in FIG. 6A. The emission layer EMLd may include the first sub-emission layer EM1a, the first charge generation layer CGLa, a second sub-emission layer EM2c, the second charge generation layer CGLb, and the third sub-emission layer EM3a that may be sequentially stacked on each other in the third direction DR3.

The second sub-emission layer EM2c may include a (2-1)-th sub-emission layer EM2c-1, a (2-2)-th sub-emission layer EM2c-2, and a (2-3)-th sub-emission layer EM2c-3 that emit lights of different colors. The (2-1)-th sub-emission layer EM2c-1), the (2-2)-th sub-emission layer EM2c-2, and the (2-3)-th sub-emission layer EM2c-3 may contact each other.

For example, the (2-1)-th sub-emission layer EM2c-1 may emit a red light, the (2-2)-th sub-emission layer EM2c-2 may emit a yellow light, and the (2-3)-th sub-emission layer EM2c-3 may emit a green light. In an embodiment, the (2-1)-th sub-emission layer EM2c-1 may emit a green light, the (2-2)-th sub-emission layer EM2c-2 may emit a yellow light, and the (2-3)-th sub-emission layer EM2c-3 may emit a red light.

Although not illustrated, a hole control layer may be further disposed between the first charge generation layer CGLa and the second charge generation layer CGLb, and an electron control layer may be further disposed between the second charge generation layer CGLb and the second sub-emission layer EM2c. A charge control layer may be further disposed between the third sub-emission layer EM3a and the second charge generation layer CGLb. A buffer layer may be further provided on the third sub-emission layer EM3a.

FIGS. 6F, 6G, and 6H are schematic cross-sectional views illustrating stacked structures of light emitting elements ED-R, ED-G, and ED-B respectively disposed in emission areas, according to an embodiment of the disclosure.

Referring to FIGS. 6F, 6G, and 6H, the first light emitting element ED-R may be disposed in a red emission area, the second light emitting element ED-G may be disposed in a green emission area, and the third light emitting element ED-B may be disposed in a blue emission area. The first light emitting element ED-R, the second light emitting element ED-G, and the third light emitting element ED-B may include the following common layers: the hole control layer HCL, an intermediate electron transport layer METL, a charge generation layer CGL-1, an intermediate hole transport layer MHTL, a buffer layer EBFL, the electron control layer ECL, and the cathode CE. For example, the common layers such as the hole control layer HCL, the intermediate electron transport layer METL, the charge generation layer CGL-1, the intermediate hole transport layer MHTL, the buffer layer EBFL, the electron control layer ECL, and the cathode CE may be formed in common at the pixels PX (refer to FIG. 3).

Some of lights emitted from the first to third light emitting elements ED-R, ED-G, and ED-B may primarily resonate, and the others thereof may secondarily resonate. A thickness of the cathode CE may be about 120 angstroms, and thus, a strong resonance structure may be implemented.

The hole control layer HCL may include a hole injection layer HIL and the hole transport layer HTL disposed on the hole injection layer HIL. The charge generation layer CGL-1 may include an n-type charge generation layer N-CGL and a p-type charge generation layer P-CGL. For example, the p-type charge generation layer P-CGL may be a charge generation layer that provides holes to stacks adjacent thereto. The n-type charge generation layer N-CGL may be a charge generation layer that provides electrons to stacks adjacent thereto. Each of the charge generation layers described with reference to FIGS. 6B, 6C, 6D, and 6E may include the n-type charge generation layer N-CGL and the p-type charge generation layer P-CGL.

Each of the first to third light emitting elements ED-R, ED-G, and ED-B may include at least two stacks disposed between the corresponding anode AE-R/AE-G/AE-B and the cathode CE. For example, a first stack may be disposed between the corresponding anode AE-R/AE-G/AE-B and the charge generation layer CGL-1, and a second stack may be disposed between the charge generation layer CGL-1 and the cathode CE.

A first stack STR1 of the first light emitting element ED-R may include the hole control layer HCL, a first red emission layer EMR1 and the intermediate electron transport layer METL, and a second stack STR2 of the first light emitting element ED-R may include the intermediate hole transport layer MHTL, an auxiliary layer SEMR, a second red emission layer EMR2, the buffer layer EBFL, and the electron control layer ECL. The auxiliary layer SEMR may perform a role of adjusting a resonant distance such that a light is capable of being extracted with maximum efficiency.

A first stack STG1 of the second light emitting element ED-G may include the hole control layer HCL, a first green emission layer EMG1 and the intermediate electron transport layer METL, and a second stack STG2 of the second light emitting element ED-G may include the intermediate hole transport layer MHTL, a second green emission layer EMG2, the buffer layer EBFL, and the electron control layer ECL. The second light emitting element ED-G may not include an auxiliary layer. Accordingly, the second green emission layer EMG2 may be directly disposed on the intermediate hole transport layer MHTL.

A first stack STB1 of the third light emitting element ED-B may include the hole control layer HCL, a first blue emission layer EMB1 and the intermediate electron transport layer METL, and a second stack STB2 of the third light emitting element ED-B may include the intermediate hole transport layer MHTL, a second blue emission layer EMB2, the buffer layer EBFL, and the electron control layer ECL.

The first red emission layer EMR1, the first green emission layer EMG1, and the first blue emission layer EMB1 may be provided in corresponding emission areas, respectively. For example, the first red emission layer EMR1, the first green emission layer EMG1, and the first blue emission layer EMB1 may be formed in corresponding pixels so as to be separated from each other. The second red emission layer EMR2, the second green emission layer EMG2, and the second blue emission layer EMB2 may be respectively provided in the corresponding emission areas and may be formed in the corresponding pixels so as to be separated from each other.

Thicknesses of the first red emission layer EMR1, the first green emission layer EMG1, and the first blue emission layer EMB1 may be different, and thicknesses of the second red emission layer EMR2, the second green emission layer EMG2, and the second blue emission layer EMB2 may be different. For example, the thickness of the first red emission layer EMR1 may be greater than the thickness of the first green emission layer EMG1, and the thickness of the first green emission layer EMG1 may be greater than the thickness of the first blue emission layer EMB1. The thickness of the second red emission layer EMR2 may be greater than the thickness of the second green emission layer EMG2, and the thickness of the second green emission layer EMG2 may be greater than the thickness of the second blue emission layer EMB2.

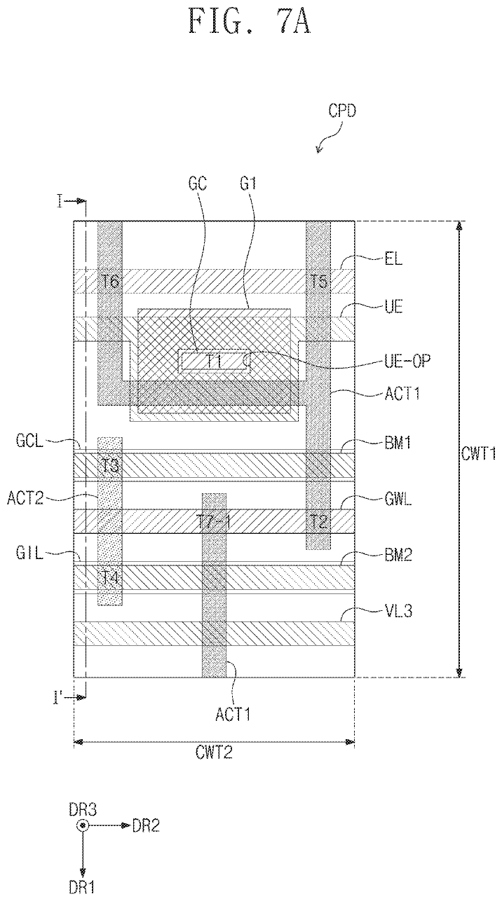

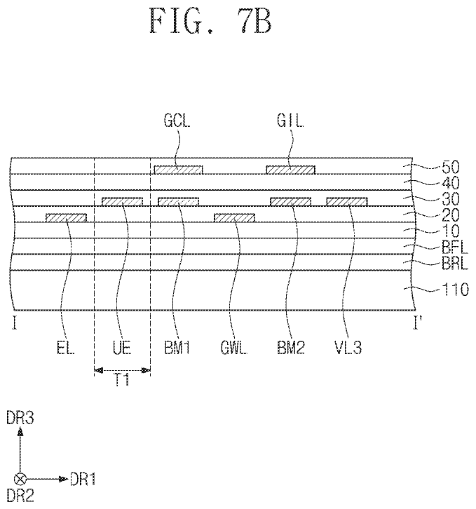

FIG. 7A is a schematic plan view illustrating a portion CPD of a pixel driving circuit according to a comparative example of the disclosure. FIG. 7B is a schematic cross-sectional view taken along line I-I′ of FIG. 7A.

Referring to FIG. 7A, the first to sixth transistors T1, T2, T3, T4, T5, and T6 of the pixel PXij (refer to FIG. 4) and a seventh transistor T7-1 of another pixel are illustrated. For example, the seventh transistor T7-1 may have the third electrode connected with the j-th write scan line GWLj. The portion CPD may be repeatedly disposed in the first direction DR1 and the second direction DR2. Alternatively, the portion CPD and another portion symmetrical to the portion CPD may be repeatedly arranged in the second direction DR2.

Referring to FIGS. 7A and 7B, a first semiconductor pattern ACT1 may be disposed between the buffer layer BFL and the first insulating layer 10. The first semiconductor pattern ACT1 may include a silicon semiconductor. For example, the silicon semiconductor may include amorphous silicon or polycrystalline silicon. For example, the first semiconductor pattern ACT1 may include low-temperature polycrystalline silicon (LTPS).

The emission control line EL, the write scan line GWL, and the third electrode G1 may be disposed between the first insulating layer 10 and the second insulating layer 20. The emission control line EL, the write scan line GWL, and the third electrode G1 may include metal, alloy, conductive metal oxide, transparent conductive material, or a combination thereof. For example, the emission control line EL, the write scan line GWL, and the third electrode G1 may include silver (Ag), an alloy containing silver (Ag), molybdenum (Mo), an alloy containing molybdenum (Mo), aluminum (Al), an alloy containing aluminum (Al), an aluminum nitride (AlN), tungsten (W), tungsten nitride (WN), copper (Cu), indium tin oxide (ITO), indium zinc oxide (IZO), or a combination thereof, but is not specifically limited thereto.

The emission control line EL and the write scan line GWL may extend in the second direction DR2. The emission control line EL may constitute the fifth and sixth transistors T5 and T6 together with the first semiconductor pattern ACT1. The write scan line GWL may constitute the second transistor T2 and the seventh transistor T7-1 together with the first semiconductor pattern ACT1. The third electrode G1 may be disposed in the shape of an island (e.g., isolated). The third electrode G1 may constitute the first transistor T1 together with the first semiconductor pattern ACT1.

The upper electrode UE, a first shielding electrode BM1, a second shielding electrode BM2, and the first initialization voltage line VL3 may be disposed between the second insulating layer 20 and the third insulating layer 30. However, the disclosure is not limited thereto. For example, the first shielding electrode BM1 and the second shielding electrode BM2 may be disposed on any other layer, not between the first insulating layer 10 and the second insulating layer 20.

The upper electrode UE may overlap the third electrode G1 and may extend in the second direction DR2. For example, the upper electrode UE may constitute the storage capacitor Cst (refer to FIG. 4) together with the third electrode G1. An opening UE-OP penetrating the upper electrode UE may be provided in the upper electrode UE, and the third electrode G1 may be exposed through the opening UE-OP.

Each of the first shielding electrode BM1, the second shielding electrode BM2, and the first initialization voltage line VL3 may extend in the second direction DR2. The first shielding electrode BM1 may block a light incident onto the channel of the third transistor T3, and the second shielding electrode BM2 may block a light incident onto the channel of the fourth transistor T4. Accordingly, the first shielding electrode BM1 and the second shielding electrode BM2 may prevent voltage-current characteristics of the third transistor T3 and the fourth transistor T4 from changing due to an external light.

A second semiconductor pattern ACT2 may be disposed between the third insulating layer 30 and the fourth insulating layer 40. The second semiconductor pattern ACT2 may include an oxide semiconductor. In a plan view, the first semiconductor pattern ACT1 and the second semiconductor pattern ACT2 may not overlap each other and may be spaced from each other.

A transfer pattern GC, a compensation scan line GCL, and an initialization scan line GIL may be disposed between the fourth insulating layer 40 and the fifth insulating layer 50. The transfer pattern GC may be in contact with the third electrode G1 exposed by the opening UE-OP of the upper electrode UE.

Each of the compensation scan line GCL and the initialization scan line GIL may extend in the second direction DR2. In a plan view, the compensation scan line GCL may overlap the first shielding electrode BM1, and the initialization scan line GIL may overlap the second shielding electrode BM2. The compensation scan line GCL may constitute the third transistor T3 together with the second semiconductor pattern ACT2, and the initialization scan line GIL may constitute the fourth transistor T4 together with the second semiconductor pattern ACT2.

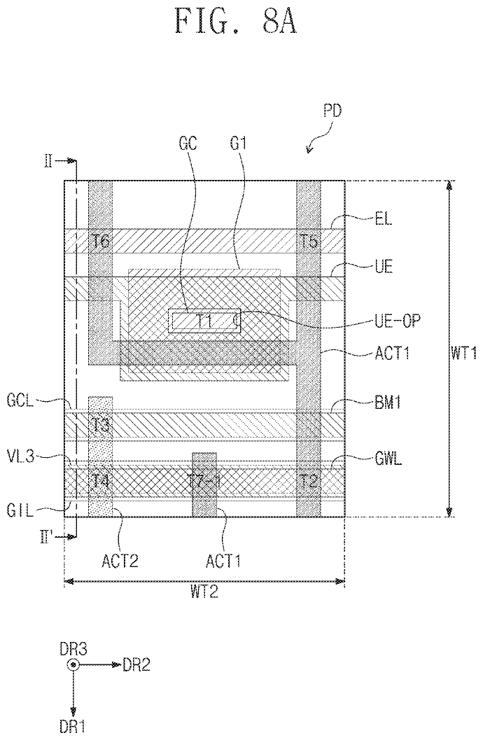

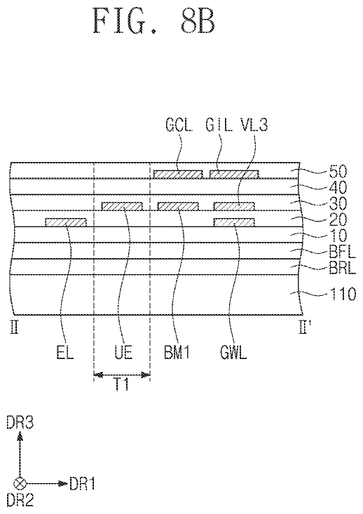

FIG. 8A is a schematic plan view illustrating a portion PD of a pixel driving circuit according to an embodiment of the disclosure. FIG. 8B is a schematic cross-sectional view taken along line II-II′ of FIG. 8A.

Referring to FIG. 8A, the portion PD of the pixel driving circuit may be repeatedly disposed along the first direction DR1 and the second direction DR2. Alternatively, the portion PD and another portion symmetrical to the portion PD may be repeatedly alternately arranged in the second direction DR2.

Referring to FIGS. 8A and 8B, in a plan view, at least three of the emission control line EL, the write scan line GWL, the compensation scan line GCL, the initialization scan line GIL, and the first initialization voltage line VL3 may overlap each other.

According to the comparative example of the disclosure, the emission control line EL, the write scan line GWL, the compensation scan line GCL, the initialization scan line GIL, and the first initialization voltage line VL3 may not overlap each other. According to an embodiment of the disclosure, as at least three lines extending in the second direction DR2 overlap each other, a width WT1 of the portion PD in the first direction DR1 may be smaller than a width CWT1 (refer to FIG. 7A) of the portion CPD in the first direction DR1, and a width WT2 of the portion PD in the second direction DR2 may be substantially the same as a width CWT2 (refer to FIG. 7A) of the portion CPD in the second direction DR2. For example, as at least three lines overlap each other, the area of the portion PD may be decreased, and the number of pixels capable of being disposed in the same area may increase. Accordingly, the resolution of the display device 1000 (refer to FIG. 1) may become higher.

According to an embodiment of the disclosure, the first initialization voltage line VL3 may be disposed between one of the emission control line EL, the write scan line GWL, the compensation scan line GCL, and the initialization scan line GIL and another of the emission control line EL, the write scan line GWL, the compensation scan line GCL, and the initialization scan line GIL.

In a cross-sectional view, for example, when viewed in the second direction DR2, the first initialization voltage line VL3 may be disposed between the write scan line GWL and the initialization scan line GIL. A first line of the three lines may be the first initialization voltage line VL3, a second line thereof may be the write scan line GWL, and a third line thereof may be the initialization scan line GIL. The first line may be disposed between the second line and the third line. In a plan view, for example, when viewed in the third direction DR3, the first initialization voltage line VL3, the write scan line GWL, and the initialization scan line GIL may overlap each other. As the first initialization voltage line VL3 may be disposed under the initialization scan line GIL, the second shielding electrode BM2 illustrated in FIGS. 7A and 7B may be omitted.

A signal that is provided to each of the write scan line GWL and the initialization scan line GIL may be a signal whose level changes. A negative constant voltage may be provided to the first initialization voltage line VL3. For example, the first initialization voltage VINT1 (refer to FIG. 4) that is provided to the first initialization voltage line VL3 may be a voltage of −3.5 V, but is not specifically limited thereto. As the first initialization voltage line VL3 may be disposed between the write scan line GWL and the initialization scan line GIL, a noise coming from the write scan line GWL or a noise coming from the initialization scan line GIL may be shielded by the first initialization voltage line VL3.

According to an embodiment of the disclosure, at least three lines connected with one pixel PXij (refer to FIG. 4) may overlap each other. Accordingly, the display panel 100 (refer to FIG. 3) having the highly-integrated line arrangement may be provided, and the high-resolution display panel 100 (refer to FIG. 3) may be provided. A line disposed in the middle from among the three lines may be a line to which a constant voltage may be provided, for example, may be the first initialization voltage line VL3. Accordingly, a noise may be shielded by the line disposed in the middle from among the three lines. As a result, the mutual influence of lines overlapping each other may be minimized.

The first semiconductor pattern ACT1 may include a silicon semiconductor. For example, the silicon semiconductor may include amorphous silicon or polycrystalline silicon. For example, the first semiconductor pattern ACT1 may include low-temperature polycrystalline silicon (LTPS). The second semiconductor pattern ACT2 may include an oxide semiconductor. In a plan view, the first semiconductor pattern ACT1 and the second semiconductor pattern ACT2 may not overlap each other and may be spaced from each other.

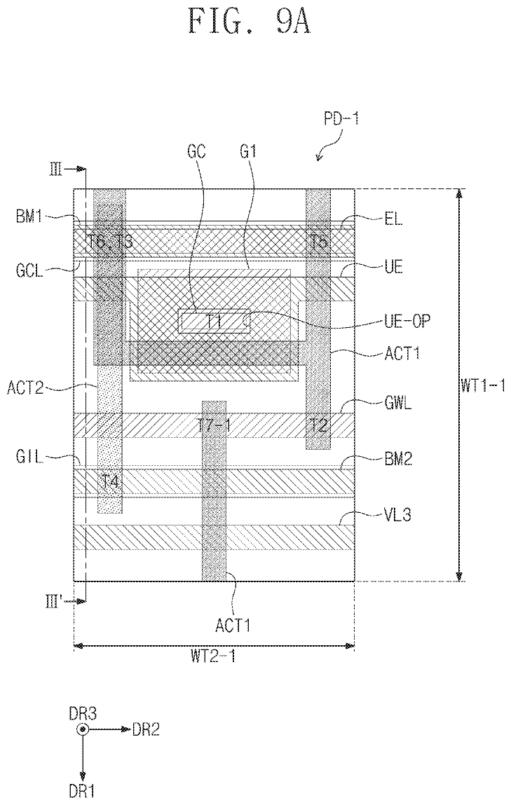

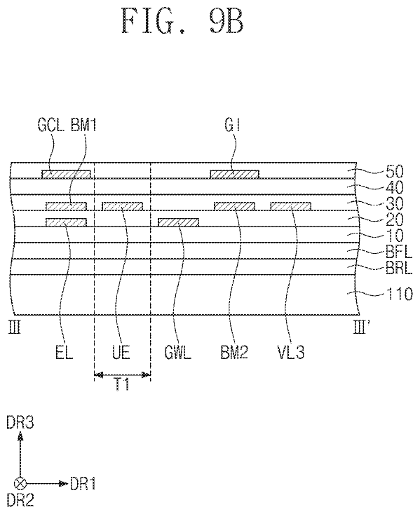

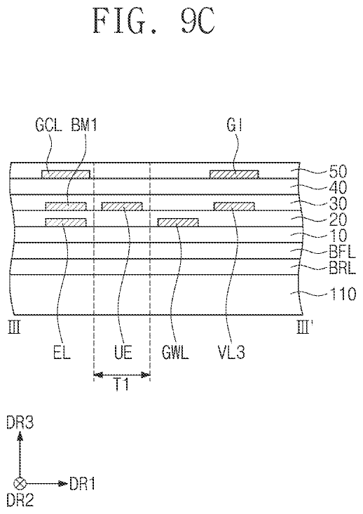

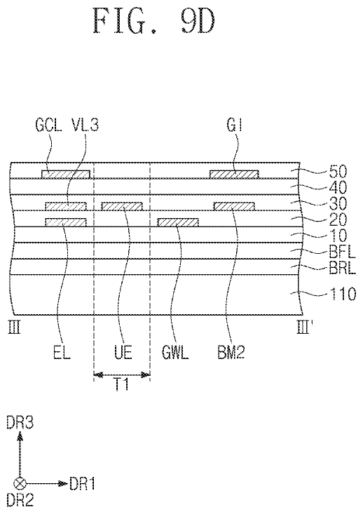

FIG. 9A is a schematic plan view illustrating a portion PD-1 of a pixel driving circuit according to an embodiment of the disclosure. FIG. 9B is a schematic cross-sectional view taken along line III-III′ of FIG. 9A.

Referring to FIGS. 9A and 9B, in a plan view, at least three of the emission control line EL, the write scan line GWL, the compensation scan line GCL, the initialization scan line GIL, the first initialization voltage line VL3, the first shielding electrode BM1, and the second shielding electrode BM2 may overlap each other. According to an embodiment of the disclosure, as at least three lines extending in the second direction DR2 overlap each other, a width WT1-1 of the portion PD-1 in the first direction DR1 may be smaller than the width CWT1 (refer to FIG. 7A) of the portion CPD in the first direction DR1, and a width WT2-1 of the portion PD-1 in the second direction DR2 may be substantially the same as the width CWT2 (refer to FIG. 7A) of the portion CPD in the second direction DR2. For example, as at least three lines overlap each other, the area of the portion PD-1 may be decreased, and the number of pixels capable of being disposed in the same area may increase. Accordingly, the resolution of the display device 1000 (refer to FIG. 1) may become higher.

According to an embodiment of the disclosure, the emission control line EL, the first shielding electrode BM1, and the compensation scan line GCL may overlap each other. The compensation scan line GCL may constitute the third transistor T3 together with the second semiconductor pattern ACT2, and the emission control line EL may constitute the sixth transistor T6 together with the first semiconductor pattern ACT1.

In a plan view, a portion of the first semiconductor pattern ACT1 and a portion of the second semiconductor pattern ACT2 may overlap each other. In a plan view, the portion of the first semiconductor pattern ACT1 and the portion of the second semiconductor pattern ACT2 may overlap each other at an overlapping portion of the emission control line EL and the compensation scan line GCL. In this case, the third transistor T3 and the sixth transistor T6 may overlap each other.

FIG. 9C is a schematic cross-sectional view illustrating a portion of a pixel driving circuit according to an embodiment of the disclosure. A difference between pixel driving circuits of FIGS. 9B and 9C will be described.

Referring to FIG. 9C, as the first initialization voltage line VL3 may be disposed under the initialization scan line GIL, the second shielding electrode BM2 illustrated in FIG. 9B may be omitted.

FIG. 9D is a schematic cross-sectional view illustrating a portion of a pixel driving circuit according to an embodiment of the disclosure. A difference between pixel driving circuits of FIGS. 9B and 9D will be described.

Referring to FIG. 9D, the emission control line EL, the first initialization voltage line VL3, and the compensation scan line GCL may overlap each other. Accordingly the first shielding electrode BM1 illustrated in FIG. 9B may be omitted.

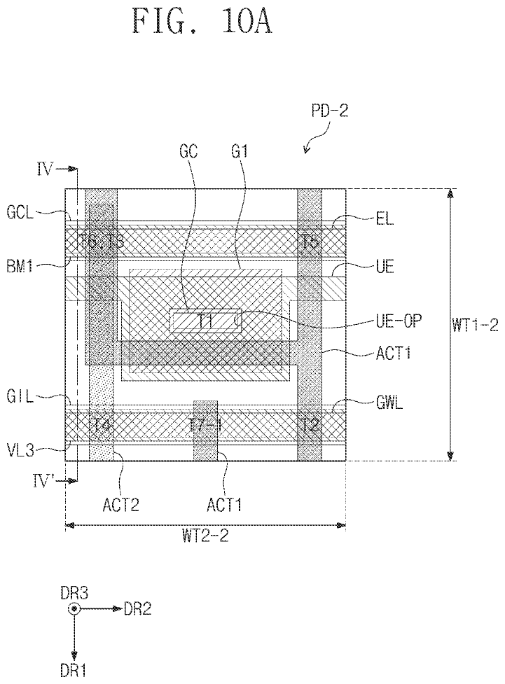

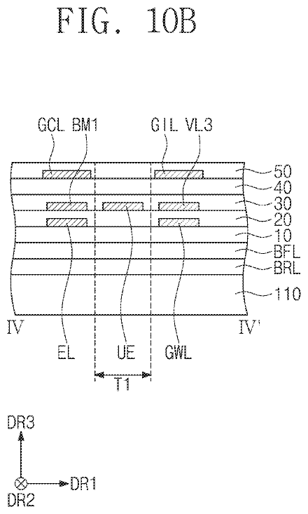

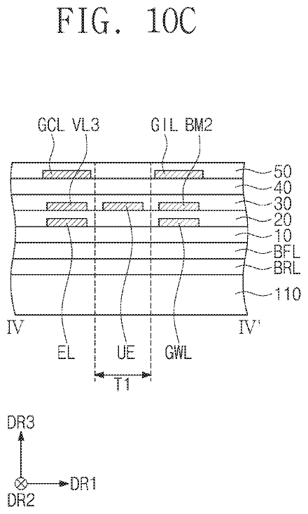

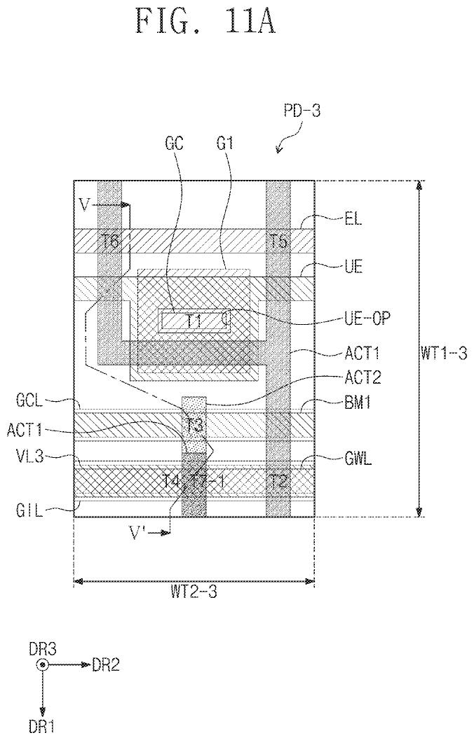

FIG. 10A is a schematic plan view illustrating a portion of a pixel driving circuit according to an embodiment of the disclosure. FIG. 10B is a schematic cross-sectional view taken along line IV-IV′ of FIG. 10A.

Referring to FIGS. 10A and 10B, in a plan view, at least three of the emission control line EL, the write scan line GWL, the compensation scan line GCL, the initialization scan line GIL, the first initialization voltage line VL3, the first shielding electrode BM1, and the second shielding electrode BM2 may overlap each other.

According to an embodiment of the disclosure, the emission control line EL, the first shielding electrode BM1, and the compensation scan line GCL may overlap each other, and the first initialization voltage line VL3, the write scan line GWL, and the initialization scan line GIL may overlap each other. According to an embodiment of the disclosure, as at least three lines extending in the second direction DR2 overlap each other, a width WT1-2 of a portion PD-2 in the first direction DR1 may be smaller than the width CWT1 (refer to FIG. 7A) of the portion CPD in the first direction DR1, and a width WT2-2 of the portion PD-2 in the second direction DR2 may be substantially the same as the width CWT2 (refer to FIG. 7A) of the portion CPD in the second direction DR2.

FIG. 10C is a schematic cross-sectional view illustrating a portion of a pixel driving circuit according to an embodiment of the disclosure. A difference between pixel driving circuits of FIGS. 10B and 10C will be described.

Referring to FIG. 10C, the emission control line EL, the first initialization voltage line VL3, and the compensation scan line GCL may overlap each other, and the write scan line GWL, the second shielding electrode BM2, and the initialization scan line GIL may overlap each other.

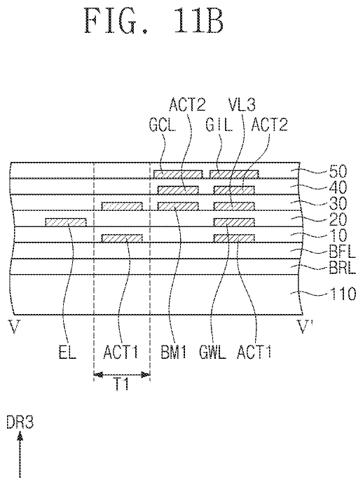

FIG. 11A is a schematic plan view illustrating a portion of a pixel driving circuit according to an embodiment of the disclosure. FIG. 11B is a schematic cross-sectional view taken along line V-V′ of FIG. 11A.

Referring to FIGS. 11A and 111B, in a plan view, at least three of the emission control line EL, the write scan line GWL, the compensation scan line GCL, the initialization scan line GIL, and the first initialization voltage line VL3 may overlap each other. According to an embodiment of the disclosure, as at least three lines extending in the second direction DR2 overlap each other, a width WT1-3 of a portion PD-3 in the first direction DR1 may be smaller than the width CWT1 (refer to FIG. 7A) of the portion CPD in the first direction DR1.

At least a portion of the second semiconductor pattern ACT2 may overlap at least a portion of the first semiconductor pattern ACT1. For example, the second semiconductor pattern ACT2 may overlap a portion of the first semiconductor pattern ACT1 constituting the seventh transistor T7-1. As the first semiconductor pattern ACT1 and the second semiconductor pattern ACT2 overlap each other, the fourth transistor T4 and the seventh transistor T7-1 may overlap each other. Accordingly, a width WT2-3 of the portion PD-3 in the second direction DR2 may be smaller than the width CWT2 (refer to FIG. 7A) of the portion CPD in the second direction DR2.

Contact areas that contact wires disposed in different layers may be defined in each of the first semiconductor pattern ACT1 and the second semiconductor pattern ACT2. For example, first contact areas may be defined in the first semiconductor pattern ACT1, and second contact areas may be defined in the second semiconductor pattern ACT2. The first contact areas and the second contact areas may be defined in an area where the first semiconductor pattern ACT1 and the second semiconductor pattern ACT2 may not overlap each other. For example, in a plan view, a distance between the first contact area defined in the first semiconductor pattern ACT1 and the second contact area defined in the second semiconductor pattern ACT2 may be 1.5 micrometers or more.

In a cross-sectional view, the first initialization voltage line VL3 and the write scan line GWL may be disposed between a portion of the first semiconductor pattern ACT1 and a portion of the second semiconductor pattern ACT2. In a plan view, for example, when viewed in the third direction DR3, the first initialization voltage line VL3, the write scan line GWL, the initialization scan line GIL, and the portion of the first semiconductor pattern ACT1, and the portion of the second semiconductor pattern ACT2 may overlap each other.

According to this embodiment, as at least three lines overlap each other and the first semiconductor pattern ACT1 and the second semiconductor pattern ACT2 overlap each other, the area of the portion PD-3 may be decreased, and the number of pixels capable of being disposed in the same area may increase. Accordingly, the resolution of the display device 1000 (refer to FIG. 1) may become higher.

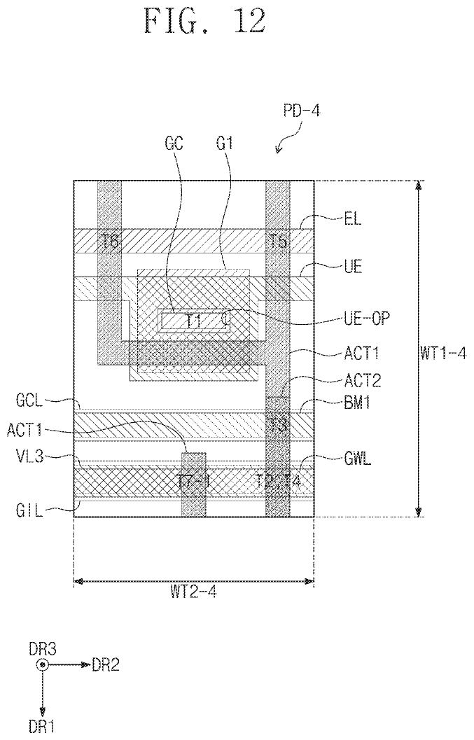

FIG. 12 is a schematic plan view illustrating a portion of a pixel driving circuit according to an embodiment of the disclosure. A difference between pixel driving circuits of FIGS. 11A and 12 will be described.

Referring to FIG. 12, the second semiconductor pattern ACT2 may overlap a portion of the first semiconductor pattern ACT1. For example, the second semiconductor pattern ACT2 may overlap a portion of the first semiconductor pattern ACT1 constituting the second transistor T2. As the first semiconductor pattern ACT1 and the second semiconductor pattern ACT2 overlap each other, the fourth transistor T4 and the second transistor T2 may overlap each other. The fifth transistor T5, the third transistor T3, and the overlapping second and fourth transistors T2 and T4 may be arranged in the first direction DR1.

According to an embodiment of the disclosure, as at least three lines VL3, GWL, and GIL extending in the second direction DR2 overlap each other and the first semiconductor pattern ACT1 and the second semiconductor pattern ACT2 partially overlap each other, a width WT1-4 of a portion PD-4 in the first direction DR1 may be smaller than the width CWT1 (refer to FIG. 7A) of the portion CPD in the first direction DR1, and a width WT2-4 of the portion PD-4 in the second direction DR2 may be smaller than the width CWT2 (refer to FIG. 7A) of the portion CPD in the second direction DR2. For example, as the area of the portion PD-4 is decreased, the number of pixels capable of being disposed in the same area may increase. Accordingly, the resolution of the display device 1000 (refer to FIG. 1) may become higher.

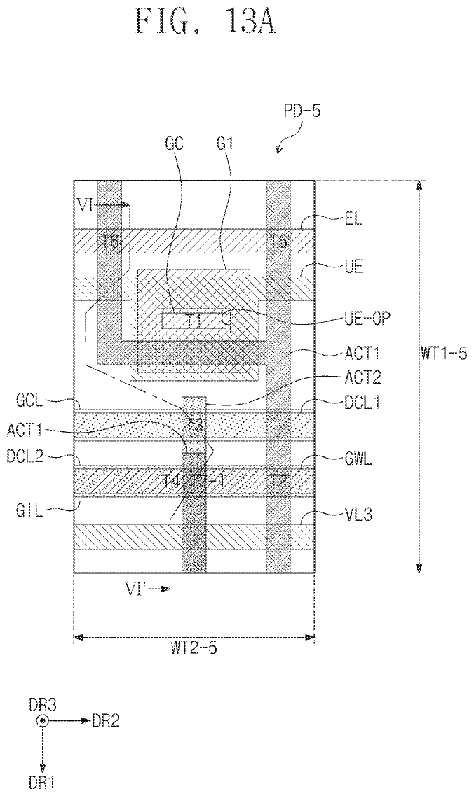

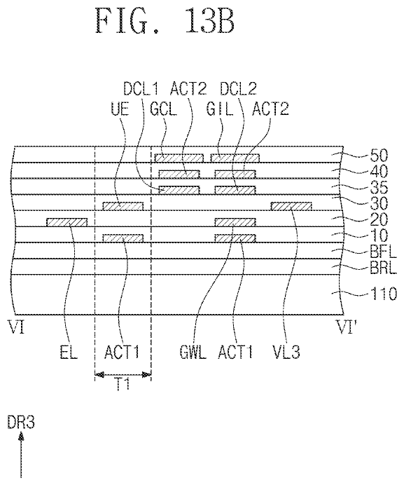

FIG. 13A is a schematic plan view illustrating a portion of a pixel driving circuit according to an embodiment of the disclosure. FIG. 13B is a schematic cross-sectional view taken along line VI-VI′ of FIG. 13A.

Referring to FIGS. 13A and 13B, a first additional constant voltage line DCL1 and a second additional constant voltage line DCL2 may be further provided. The first additional constant voltage line DCL1 may overlap a portion of the second semiconductor pattern ACT2 and the compensation scan line GCL, and the second additional constant voltage line DCL2 may overlap another portion of the second semiconductor pattern ACT2 and the initialization scan line GIL.

The first additional constant voltage line DCL1 and the second additional constant voltage line DCL2 may be disposed on the third insulating layer 30, and an additional insulating layer 35 covering the first and second additional constant voltage lines DCL1 and DCL2 may be further disposed on the third insulating layer 30. The second semiconductor pattern ACT2 may be disposed on the additional insulating layer 35, and the fourth insulating layer 40 may be disposed on the additional insulating layer 35 to cover the second semiconductor pattern ACT2.

The first additional constant voltage line DCL1 may block a light incident onto the channel of the third transistor T3, and the second additional constant voltage line DCL2 may block a light incident onto the channel of the fourth transistor T4. Accordingly, the first additional constant voltage line DCL1 and the second additional constant voltage line DCL2 may prevent voltage-current characteristics of the third transistor T3 and the fourth transistor T4 from changing due to an external light.

A negative constant voltage may be applied to each of the first additional constant voltage line DCL1 and the second additional constant voltage line DCL2. Accordingly, the first additional constant voltage line DCL1 and the second additional constant voltage line DCL2 may also perform a role of shielding a noise.

According to an embodiment of the disclosure, as at least three lines DCL2, GWL, and GIL extending in the second direction DR2 overlap each other and the first semiconductor pattern ACT1 and the second semiconductor pattern ACT2 partially overlap each other, a width WT1-5 of a portion PD-5 in the first direction DR1 may be smaller than the width CWT1 (refer to FIG. 7A) of the portion CPD in the first direction DR1, and a width WT2-5 of the portion PD-5 in the second direction DR2 may be smaller than the width CWT2 (refer to FIG. 7A) of the portion CPD in the second direction DR2. For example, as the area of the portion PD-4 is decreased, the number of pixels capable of being disposed in the same area may increase. Accordingly, the resolution of the display device 1000 (refer to FIG. 1) may become higher.

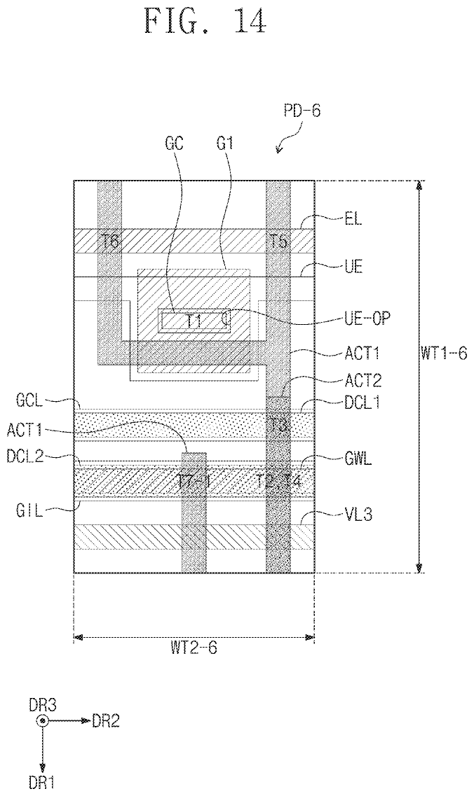

FIG. 14 is a schematic plan view illustrating a portion of a pixel driving circuit according to an embodiment of the disclosure. A difference between pixel driving circuits of FIGS. 13A and 14 will be described.

Referring to FIG. 14, the second semiconductor pattern ACT2 may overlap a portion of the first semiconductor pattern ACT1. For example, the second semiconductor pattern ACT2 may overlap a portion of the first semiconductor pattern ACT1 constituting the second transistor T2. As the first semiconductor pattern ACT1 and the second semiconductor pattern ACT2 overlap each other, the fourth transistor T4 and the second transistor T2 may overlap each other. The fifth transistor T5, the third transistor T3, and the overlapping second and fourth transistors T2 and T4 may be arranged in the first direction DR1.

According to an embodiment of the disclosure, as at least three lines DCL2, GWL, and GIL extending in the second direction DR2 overlap each other and the first semiconductor pattern ACT1 and the second semiconductor pattern ACT2 partially overlap each other, a width WT1-6 of a portion PD-6 in the first direction DR1 may be smaller than the width CWT1 (refer to FIG. 7A) of the portion CPD in the first direction DR1, and a width WT2-6 of the portion PD-6 in the second direction DR2 may be smaller than the width CWT2 (refer to FIG. 7A) of the portion CPD in the second direction DR2. For example, as the area of the portion PD-6 is decreased, the number of pixels capable of being disposed in the same area may increase. Accordingly, the resolution of the display device 1000 (refer to FIG. 1) may become higher.

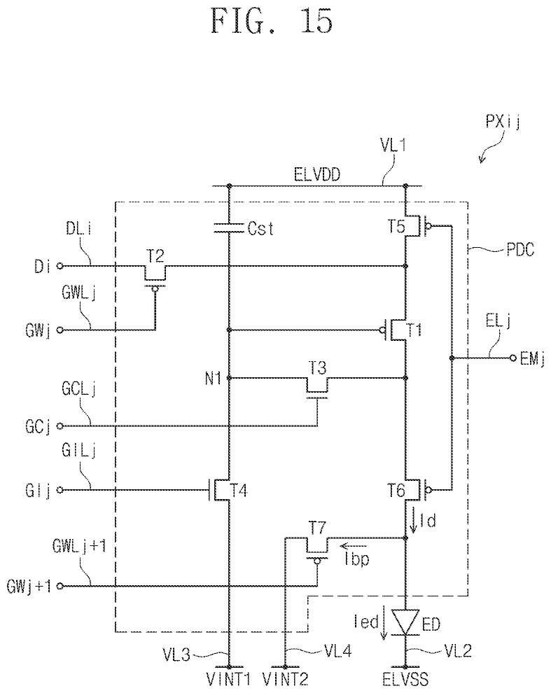

FIG. 15 is a schematic circuit diagram illustrating a pixel according to an embodiment of the disclosure. A difference between pixels of FIGS. 15 and 4 will be described. Components that may be the same as components described with reference to FIG. 4 are marked by the same reference signs, and thus, additional description will be omitted to avoid redundancy.

Referring to FIG. 15, the pixel driving circuit PDC may be further provided with the second initialization voltage VINT2 through a second initialization voltage line VL4. A seventh transistor T7 may include a first electrode connected with the second initialization voltage line VL4 to which the second initialization voltage VINT2 is applied, a second electrode connected with the second electrode of the sixth transistor T6, and a third electrode connected with the (j+1)-th write scan line GWLj+1.

As an example of the disclosure, the second initialization voltage VINT2 may be a negative constant voltage. The second initialization voltage VINT2 may be different from the first initialization voltage VINT1. For example, the first initialization voltage VINT1 may be −3.5 V, and the second initialization voltage VINT2 may be −2.5 V. However, the disclosure is not limited thereto.

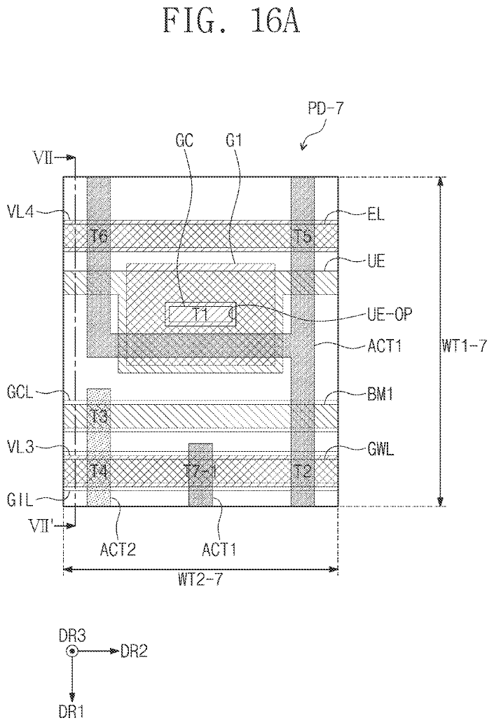

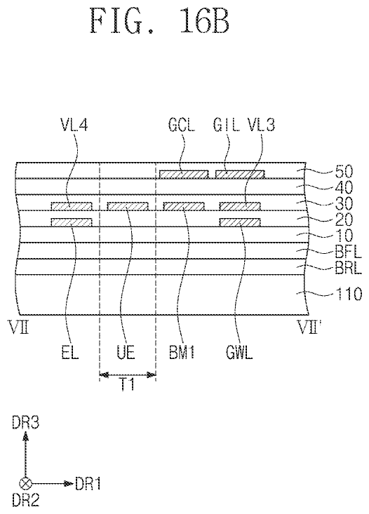

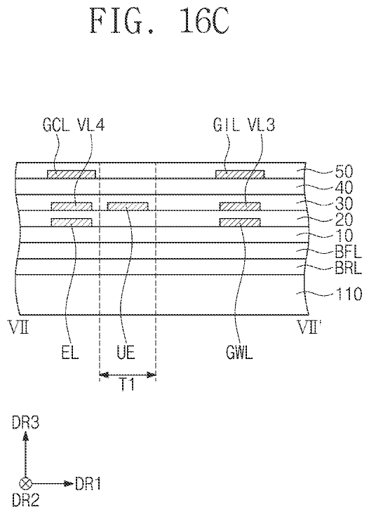

FIG. 16A is a schematic plan view illustrating a portion of a pixel driving circuit according to an embodiment of the disclosure. FIG. 16B is a schematic cross-sectional view taken along line VII-VII′ of FIG. 16A.

Referring to FIGS. 16A and 16B, each of the first initialization voltage line VL3 and the second initialization voltage line VL4 may overlap at least one of the emission control line EL, the write scan line GWL, the compensation scan line GCL, and the initialization scan line GIL.

For example, in a plan view, the first initialization voltage line VL3, the write scan line GWL, and the initialization scan line GIL may overlap each other, and the second initialization voltage line VL4 and the emission control line EL may overlap each other. In a cross-sectional view, the first initialization voltage line VL3 may be disposed between the write scan line GWL and the initialization scan line GIL, and the second initialization voltage line VL4 may be disposed over the emission control line EL. As at least some of lines extending in the second direction DR2 overlap each other, a width WT1-7 of a portion PD-7 in the first direction DR1 may be smaller than the width CWT1 (refer to FIG. 7A) of the portion CPD in the first direction DR1. A width WT2-7 of the portion PD-7 in the second direction DR2 may be substantially the same as the width CWT2 (refer to FIG. 7A) of the portion CPD in the second direction DR2.

FIG. 16C is a schematic cross-sectional view illustrating a portion of a pixel driving circuit according to an embodiment of the disclosure. A difference between pixel driving circuits of FIGS. 16B and 16C will be described.

Referring to FIG. 16C, each of the first initialization voltage line VL3 and the second initialization voltage line VL4 may be disposed between two lines of the emission control line EL, the write scan line GWL, the compensation scan line GCL, and the initialization scan line GIL. For example, the first initialization voltage line VL3 may be disposed between the initialization scan line GIL and the write scan line GWL, and the second initialization voltage line VL4 may be disposed between the compensation scan line GCL and the emission control line EL.

A negative constant voltage may be applied to each of the first initialization voltage line VL3 and the second initialization voltage line VL4. For example, signals that may be provided to an upper line and a lower line may be shielded by the first initialization voltage line VL3 and the second initialization voltage line VL4, each of which is a line disposed in the middle from among three lines overlapping each other. As a result, the mutual influence of lines overlapping each other may be minimized.

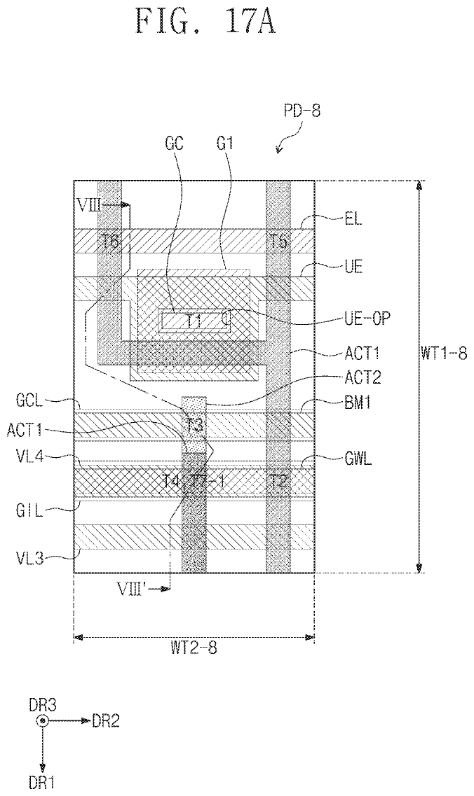

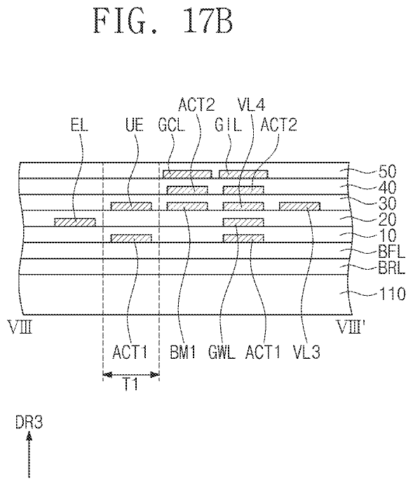

FIG. 17A is a schematic plan view illustrating a portion of a pixel driving circuit according to an embodiment of the disclosure. FIG. 17B is a schematic cross-sectional view taken along line VIII-VIII′ of FIG. 17A.

Referring to FIGS. 17A and 17B, the second initialization voltage line VL4 may overlap the write scan line GWL and the initialization scan line GIL. An example in which the first initialization voltage line VL3 does not overlap any other lines is illustrated, but the first initialization voltage line VL3 may overlap the emission control line EL or may overlap the compensation scan line GCL. In the case where the first initialization voltage line VL3 overlaps the compensation scan line GCL, the first shielding electrode BM1 may be omitted.

In a cross-sectional view, the write scan line GWL may be disposed over the first semiconductor pattern ACT1, the second initialization voltage line VL4 may be disposed over the write scan line GWL, the second semiconductor pattern ACT2 may be disposed over the second initialization voltage line VL4, and the initialization scan line GIL may be disposed over the second semiconductor pattern ACT2.

A portion of the second semiconductor pattern ACT2 may overlap a portion of the first semiconductor pattern ACT1. For example, the second semiconductor pattern ACT2 may overlap a portion of the first semiconductor pattern ACT1 constituting the seventh transistor T7-1. As the first semiconductor pattern ACT1 and the second semiconductor pattern ACT2 overlap each other, the fourth transistor T4 and the seventh transistor T7-1 may overlap each other.

According to an embodiment of the disclosure, as at least three lines VL4, GWL, and GIL extending in the second direction DR2 overlap each other and the first semiconductor pattern ACT1 and the second semiconductor pattern ACT2 partially overlap each other, a width WT1-8 of a portion PD-8 in the first direction DR1 may be smaller than the width CWT1 (refer to FIG. 7A) of the portion CPD in the first direction DR1, and a width WT2-8 of the portion PD-8 in the second direction DR2 may be smaller than the width CWT2 (refer to FIG. 7A) of the portion CPD in the second direction DR2. For example, as the area of the portion PD-8 is decreased, the number of pixels capable of being disposed in the same area may increase. Accordingly, the resolution of the display device 1000 (refer to FIG. 1) may become higher.

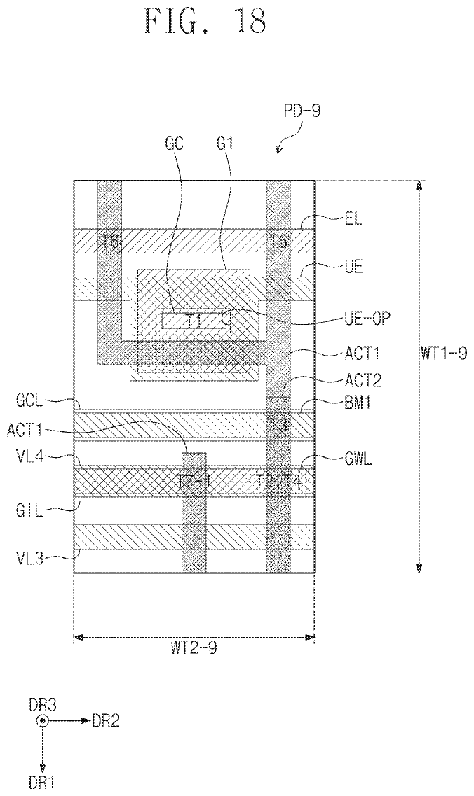

FIG. 18 is a schematic plan view illustrating a portion of a pixel driving circuit according to an embodiment of the disclosure. A difference between pixel driving circuits of FIGS. 17A and 18 will be described.

Referring to FIG. 18, the second semiconductor pattern ACT2 may overlap a portion of the first semiconductor pattern ACT1. For example, the second semiconductor pattern ACT2 may overlap a portion of the first semiconductor pattern ACT1 constituting the second transistor T2. As the first semiconductor pattern ACT1 and the second semiconductor pattern ACT2 overlap each other, the fourth transistor T4 and the second transistor T2 may overlap each other. The fifth transistor T5, the third transistor T3, and the overlapping second and fourth transistors T2 and T4 may be arranged in the first direction DR1.

According to an embodiment of the disclosure, as at least three lines VL4, GWL, and GIL extending in the second direction DR2 overlap each other and the first semiconductor pattern ACT1 and the second semiconductor pattern ACT2 partially overlap each other, a width WT1-9 of a portion PD-9 in the first direction DR1 may be smaller than the width CWT1 (refer to FIG. 7A) of the portion CPD in the first direction DR1, and a width WT2-9 of the portion PD-9 in the second direction DR2 may be smaller than the width CWT2 (refer to FIG. 7A) of the portion CPD in the second direction DR2. For example, as the area of the portion PD-9 is decreased, the number of pixels capable of being disposed in the same area may increase. Accordingly, the resolution of the display device 1000 (refer to FIG. 1) may become higher.

According to the above description, at least three lines extending in a given direction may overlap each other, or at least a portion of a first semiconductor pattern disposed on a first layer may overlap at least a portion of a second semiconductor pattern disposed on a second layer different from the first layer. In this case, a width in a direction intersecting the given direction or a width in a direction parallel to the given direction may be decreased. As such, the number of pixels capable of being disposed in the same area may be increased, and a resolution of a display device may be improved.

A line disposed in the middle from among the three lines overlapping each other may be an initialization voltage line to which a constant voltage may be provided. As such, a signal-based noise between overlapping lines may be shielded by the initialization voltage line.

While the disclosure has been described with reference to embodiments thereof, it will be apparent to those of ordinary skill in the art that various changes and modifications may be made thereto without departing from the spirit and scope of the disclosure.

What is claimed is:

1. A display device comprising:
a display panel including:
a display area;
a non-display area;
a pixel disposed in the display area and including a light emitting element and a pixel driving circuit electrically connected to the light emitting element;
a data line electrically connected to the pixel and extending in a first direction;
a plurality of scan lines electrically connected to the pixel and extending in a second direction intersecting the first direction;
an emission control line electrically connected to the pixel and extending in the second direction; and
a first initialization voltage line electrically connected to the pixel, extending in the second direction, and to which a first initialization voltage is applied,
wherein the first initialization voltage line is disposed between one of the plurality of scan lines and the emission control line and another of the plurality of scan lines and the emission control line.

2. The display device of claim 1, wherein
the plurality of scan lines include:
an initialization scan line;
a compensation scan line; and
a write scan line, and
at least one of the initialization scan line, the compensation scan line, and the write scan line and at least another of the initialization scan line, the compensation scan line, and the write scan line are disposed on different layers.

3. The display device of claim 2, wherein
the pixel driving circuit includes:
a driving thin film transistor electrically connected between a driving voltage line receiving a driving voltage and the light emitting element;
a switching thin film transistor electrically connected between the data line and a first electrode of the driving thin film transistor, and that receives a first write scan signal;
a compensation thin film transistor electrically connected between a second electrode of the driving thin film transistor and a first node, and that receives a compensation scan signal;
a first initialization thin film transistor electrically connected between the first initialization voltage line and the first node, and that receives an initialization scan signal; and
a second initialization thin film transistor electrically connected between the first initialization voltage line and an anode of the light emitting element, and that receives a second write scan signal,
the first write scan signal is provided through the write scan line,
the compensation scan signal is provided through the compensation scan line,
the initialization scan signal is provided through the initialization scan line, and
the second write scan signal is provided through a write scan line electrically connected to a switching transistor of another pixel.

4. The display device of claim 3, wherein
in a plan view, the first initialization voltage line overlaps the write scan line and the initialization scan line, and
in a cross-sectional view, the first initialization voltage line is disposed between the write scan line and the initialization scan line.

5. The display device of claim 3, wherein
the pixel driving circuit further includes an operation control thin film transistor electrically connected between the driving voltage line and the driving thin film transistor, and that receives an emission control signal through the emission control line; and
an emission control thin film transistor electrically connected between the driving thin film transistor and the light emitting element, and that receives the emission control signal through the emission control line.

6. The display device of claim 5, wherein, in a plan view, the compensation scan line overlaps the emission control line.

7. The display device of claim 5, wherein
the display panel further includes a shielding line overlapping the compensation scan line in a plan view,
in a plan view, the compensation scan line, the shielding line, and the emission control line overlap each other, and
the shielding line is disposed between the compensation scan line and the emission control line.

8. The display device of claim 5, wherein
the driving thin film transistor, the switching thin film transistor, the second initialization thin film transistor, the operation control thin film transistor, and the emission control thin film transistor are P-type transistors, and
the compensation thin film transistor and the first initialization thin film transistor are N-type transistors.

9. The display device of claim 5, wherein
each of the driving thin film transistor, the switching thin film transistor, the second initialization thin film transistor, the operation control thin film transistor, and the emission control thin film transistor is a transistor having a first semiconductor pattern, and
each of the compensation thin film transistor and the first initialization thin film transistor is a transistor having a second semiconductor pattern, the first semiconductor pattern and the second semiconductor patter being disposed on different layers.

10. The display device of claim 9, wherein, in a plan view, the first semiconductor pattern and the second semiconductor pattern do not overlap each other.

11. The display device of claim 9, wherein, in a plan view, at least a portion of the second semiconductor pattern overlaps a portion of the first semiconductor pattern.

12. The display device of claim 11, wherein, in a plan view, the first initialization thin film transistor overlaps the second initialization thin film transistor or overlaps the switching thin film transistor.

13. The display device of claim 11, further including:
a first additional constant voltage line overlapping a portion of the second semiconductor pattern and the compensation scan line in a plan view; and
a second additional constant voltage line overlapping another portion of the second semiconductor pattern and the initialization scan line in a plan view.

14. The display device of claim 13, wherein a negative constant voltage is applied to each of the first additional constant voltage line and the second additional constant voltage line.

15. The display device of claim 9, wherein
the first semiconductor pattern includes a silicon semiconductor, and
the second semiconductor pattern includes an oxide semiconductor.

16. The display device of claim 2, wherein
the display panel further includes a second initialization voltage line electrically connected to the pixel, extending in the second direction, and to which a second initialization voltage different from the first initialization voltage is applied, and
the second initialization voltage line overlaps at least one of the plurality of scan lines and the emission control line in a plan view.

17. The display device of claim 16, wherein the pixel driving circuit includes:
a driving thin film transistor electrically connected between a driving voltage line receiving a driving voltage and the light emitting element;
a switching thin film transistor electrically connected between the data line and a first electrode of the driving thin film transistor, and that receives a first write scan signal;
a compensation thin film transistor electrically connected between a second electrode of the driving thin film transistor and a first node, and that receives a compensation scan signal;
a first initialization thin film transistor electrically connected between the first initialization voltage line and the first node, and that receives an initialization scan signal; and
a second initialization thin film transistor electrically connected between the second initialization voltage line and an anode of the light emitting element, and that receives a second write scan signal.

18. The display device of claim 16, wherein each of the first initialization voltage and the second initialization voltage is a negative constant voltage.

19. A display device comprising:
a display panel including:
a display area;
a non-display area;
a pixel disposed in the display area and including a light emitting element and a pixel driving circuit electrically connected to the light emitting element;
a data line electrically connected to the pixel;
a plurality of scan lines electrically connected to the pixel;
an emission control line electrically connected to the pixel;
a first initialization voltage line electrically connected to the pixel; and
a second initialization voltage line electrically connected to the pixel, wherein
the plurality of scan lines, the emission control line, and the first and second initialization voltage lines extend in a same direction, and
in a plan view, three lines of the plurality of scan lines, the emission control line, and the first and second initialization voltage lines overlap each other.

20. The display device of claim 19, wherein the pixel driving circuit includes:
a driving thin film transistor electrically connected between a driving voltage line receiving a driving voltage and the light emitting element;
a switching thin film transistor electrically connected between the data line and a first electrode of the driving thin film transistor, and that receives a first write scan signal;
a compensation thin film transistor electrically connected between a second electrode of the driving thin film transistor and a first node, and that receives a compensation scan signal;
a first initialization thin film transistor electrically connected between the first initialization voltage line and the first node, and that receives an initialization scan signal;
a second initialization thin film transistor electrically connected between the second initialization voltage line and an anode of the light emitting element, and that receives a second write scan signal;
an operation control thin film transistor electrically connected between the driving voltage line and the driving thin film transistor, and that receives an emission control signal through the emission control line; and
an emission control thin film transistor electrically connected between the driving thin film transistor and the light emitting element, and that receives the emission control signal through the emission control line.

21. The display device of claim 20, wherein
a first line being one of the three lines is one of the first and second initialization voltage lines,
a second line being another of the three lines is a scan line electrically connected to the compensation thin film transistor or the first initialization thin film transistor from among the plurality of scan lines, and
a third line being another of the three lines is a scan line electrically connected to the switching thin film transistor from among the plurality of scan lines or the emission control line.

22. The display device of claim 21, wherein the first line is disposed between the second line and the third line.

23. The display device of claim 20, wherein the three lines do not overlap the driving thin film transistor in a plan view.

24. The display device of claim 20, wherein
a first constant voltage is applied to the first initialization voltage line, and
a second constant voltage different from the first constant voltage is applied to the second initialization voltage line.

25. The display device of claim 20, wherein
each of the driving thin film transistor, the switching thin film transistor, the second initialization thin film transistor, the operation control thin film transistor, and the emission control thin film transistor is a transistor having a silicon semiconductor layer,
each of the compensation thin film transistor and the first initialization thin film transistor is a transistor having an oxide semiconductor layer, and
in a plan view, a portion of the oxide semiconductor layer overlaps a portion of the oxide semiconductor layer.

26. The display device of claim 25, wherein, in a plan view, the first initialization thin film transistor overlaps the second initialization thin film transistor or the switching thin film transistor.

27. The display device of claim 25, further comprising:
a first additional constant voltage line overlapping a portion of the oxide semiconductor layer and a first line among the three lines in a plan view; and
a second additional constant voltage line overlapping another portion of the oxide semiconductor layer and a second line among the three lines in a plan view.

28. A display device comprising:
a display panel including:
a display area;
a non-display area
a pixel disposed in the display area and including a light emitting element and a pixel driving circuit electrically connected to the light emitting element and including a plurality of transistors;
a data line electrically connected to the pixel and extending in a first direction;
plurality of scan lines electrically connected to the pixel and extending in a second direction intersecting the first direction;
an emission control line electrically connected to the pixel; and
a constant voltage line to which a constant voltage is provided and overlapping the pixel driving circuit in a plan view, wherein
at least one of the plurality of transistors includes an oxide semiconductor layer,
others of the plurality of transistors include a silicon semiconductor layer, the silicon semiconductor layer and the oxide semiconductor layer being disposed on different layers, and
in a plan view, a portion of the oxide semiconductor layer and a portion of the silicon semiconductor layer overlap each other.

29. The display device of claim 28, wherein, in a plan view, three lines of the plurality of scan lines, the emission control line, and the constant voltage line overlap each other.

30. The display device of claim 28, wherein the constant voltage line is disposed between one of the plurality of scan lines and the emission control line and another of the plurality of scan lines and the emission control line.
